(19) United States
(12) Patent Application Publication
(10) Pub. No.: US 2026/0113840 A1
(43) Pub. Date: Apr. 23, 2026

(54) PRINTED CIRCUIT BOARD AND METHOD OF MANUFACTURING THE SAME

(71) Applicant: SAMSUNG ELECTRO-MECHANICS CO., LTD., Suwon-si (KR)

(72) Inventors: Sang Hoon KIM, Suwon-si (KR); Chan Hoon KO, Suwon-si (KR); Ki Eun CHO, Suwon-si (KR); Ji Ho YOON, Suwon-si (KR); Min Jae SEONG, Suwon-si (KR)

(73) Assignee: SAMSUNG ELECTRO-MECHANICS CO., LTD., Suwon-si (KR)

(21) Appl. No.: 19/266,823

(22) Filed: Jul. 11, 2025

(30) Foreign Application Priority Data
Oct. 23, 2024 (KR) 10-2024-0146009
Dec. 17, 2024 (KR) 10-2024-0188526

(51) Int. Cl. H05K 1/11; H05K 1/02; H05K 3/40

(52) U.S. Cl. CPC H05K 1/111; H05K 1/0298; H05K 1/115; H05K 3/4007; H05K 2201/032; H05K 2201/2081

(57) ABSTRACT

A printed circuit board includes an insulating layer, a conductive pad disposed on the insulating layer, a conductive bump disposed to cover at least a portion of the conductive pad and spaced apart from the insulating layer, and a solder resist layer disposed on the insulating layer and covering at least a portion of both the conductive pad and the conductive bump. The conductive bump has a maximum width greater than that of the conductive pad. A method of manufacturing the printed circuit board is also disclosed.

### CROSS-REFERENCE TO RELATED APPLICATIONS

This application claims the benefit of priority to Korean Patent Application No. 10-2024-0188526 filed on Dec. 17, 2024 and Korean Patent Application No. 10-2024-0146009 filed on Oct. 23, 2024 with the Korean Intellectual Property Office, the disclosures of which are incorporated herein by reference in their entirety.

### BACKGROUND

### 1. FIELD

The present disclosure relates to a printed circuit board and a method of manufacturing the same.

### 2. DESCRIPTION OF RELATED ART

A pitch of a bump of a substrate connected to a flip chip die has been continuously reduced, and risks, such as issues in the mounting of solder balls, or bonding reliability, may occur. Accordingly, application of a conductive bump has been considered. However, there may be a limitation in a level of a conductive bump, and also in resolution of a width. Also, a size of a conductive bump may be affected by a size of a conductive pad, and in the case in which the size is reduced to a predetermined size or less due to influence of the conductive pad, bonding reliability with the die may become vulnerable. Also, when the pitch is reduced, these risks may increase.

### SUMMARY

An aspect of the present disclosure is to provide a printed circuit board in which a level and/or a size of a conductive bump may be increased separately from a design rule of a conductive pad, such that die bonding reliability and underfill formation stability may be improved.

Another aspect of the present disclosure is to provide a printed circuit board in which a size of a conductive pad may be reduced, such that circuit density and circuit design freedom may be improved.

According to an example embodiment, a printed circuit board includes an insulating layer; a conductive pad disposed on the insulating layer; a conductive bump disposed on the insulating layer, spaced apart from the insulating layer, and covering at least a portion of the conductive pad; and a solder resist layer disposed on the insulating layer, and covering at least a portion of each of the conductive pad and the conductive bump, wherein the conductive bump has a maximum width greater than a maximum width of the conductive pad.

According to an example embodiment, a method of manufacturing a printed circuit board includes forming a conductive pad on an insulating layer; forming a first solder resist layer covering the conductive pad on the insulating layer; exposing a portion of the conductive pad from the first solder resist layer by reducing a thickness of the first solder resist layer; forming a conductive bump covering an exposed portion of the conductive pad on the first solder resist layer; forming a second solder resist layer covering the conductive bump on the first solder resist layer; and exposing a portion of the conductive bump from the second solder resist layer by reducing a thickness of the second solder resist layer.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram illustrating an example of an electronic device system;

FIG. 2 is a perspective diagram illustrating an example of an electronic device;

FIG. 3 is a cross-sectional diagram illustrating an example of a printed circuit board according an example embodiment of the present disclosure;

FIG. 4 is a process diagram illustrating an example of manufacturing the printed circuit board illustrated in FIG. 3 according an example embodiment of the present disclosure;

FIG. 5 is a cross-sectional diagram illustrating another example of a printed circuit board according an example embodiment of the present disclosure;

FIG. 6 is a process diagram illustrating an example of manufacturing the printed circuit board illustrated in FIG. 5 according an example embodiment of the present disclosure;

FIG. 7 is a cross-sectional diagram illustrating another example of a printed circuit board according an example embodiment of the present disclosure;

FIG. 8 is a process diagram illustrating an example of manufacturing the printed circuit board illustrated in FIG. 7 according an example embodiment of the present disclosure;

FIG. 9 is a cross-sectional diagram illustrating another example of a printed circuit board according an example embodiment of the present disclosure;

FIG. 10 is a process diagram illustrating an example of manufacturing the printed circuit board illustrated in FIG. 9 according an example embodiment of the present disclosure;

FIG. 11 is a cross-sectional diagram illustrating another example of a printed circuit board according an example embodiment of the present disclosure;

FIG. 12 is a process diagram illustrating an example of manufacturing the printed circuit board illustrated in FIG. 11 according an example embodiment of the present disclosure;

FIG. 13 is a cross-sectional diagram illustrating another example of a printed circuit board according an example embodiment of the present disclosure;

FIG. 14 is a process diagram illustrating an example of manufacturing the printed circuit board illustrated in FIG. 13 according an example embodiment of the present disclosure;

FIG. 15 is a cross-sectional diagram illustrating another example of a printed circuit board according an example embodiment of the present disclosure;

FIG. 16 is a process diagram illustrating an example of manufacturing the printed circuit board illustrated in FIG. 15 according an example embodiment of the present disclosure;

FIG. 17 is a cross-sectional diagram illustrating another example of a printed circuit board according an example embodiment of the present disclosure;

FIG. 18 is a process diagram illustrating an example of manufacturing the printed circuit board illustrated in FIG. 17 according an example embodiment of the present disclosure;

FIG. 19 is a cross-sectional diagram illustrating another example of a printed circuit board according an example embodiment of the present disclosure;

FIG. 20 is a process diagram illustrating an example of manufacturing the printed circuit board illustrated in FIG. 19 according an example embodiment of the present disclosure;

FIG. 21 is a cross-sectional diagram illustrating another example of a printed circuit board according an example embodiment of the present disclosure;

FIG. 22 is a process diagram illustrating an example of manufacturing the printed circuit board illustrated in FIG. 21 according an example embodiment of the present disclosure;

FIG. 23 is a cross-sectional diagram illustrating another example of a printed circuit board according an example embodiment of the present disclosure;

FIG. 24 is a plan diagram illustrating a top view of the printed circuit board illustrated in FIG. 23; and

FIG. 25 is a cross-sectional diagram illustrating another example of a printed circuit board.

### DETAILED DESCRIPTION

Hereinafter, embodiments of the present disclosure will be described as follows with reference to the attached drawings. Some elements may be exaggerated, omitted or briefly illustrated, and the sizes of the elements do not necessarily reflect the actual sizes of these elements.

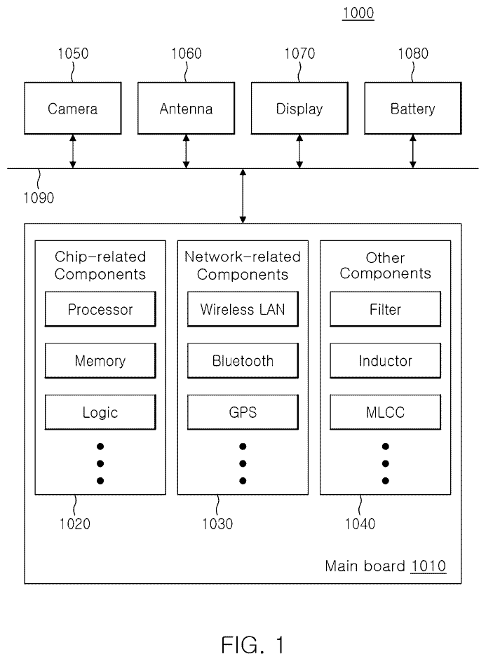

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

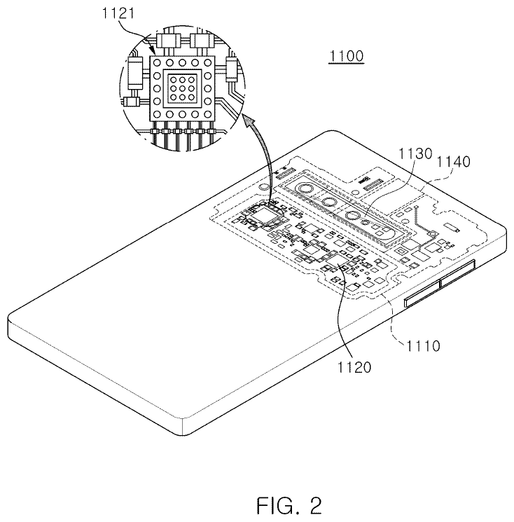

FIG. 2 is a perspective diagram illustrating an example of an electronic device.

Referring to FIG. 2, an electronic device may be a smartphone 1100, for example. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above. Also, the electronic device may be a server-related product to which a large-area substrate is required.

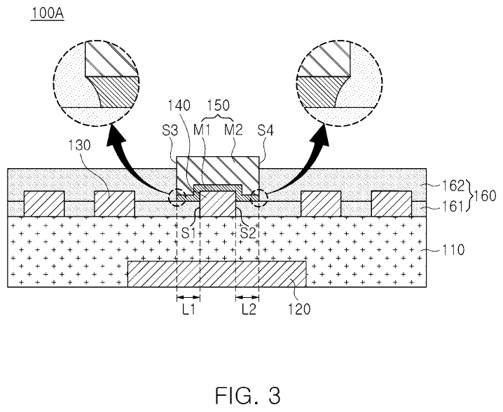

FIG. 3 is a cross-sectional diagram illustrating an example of a printed circuit board according an example embodiment.

Referring to the drawings, a printed circuit board 100A according to an example may include an insulating layer 110, a first conductive pattern 120 disposed in the insulating layer 110, a second conductive pattern 130 and a conductive pad 140 disposed on the insulating layer 110, a conductive bump 150 disposed on the insulating layer 110, spaced apart from the insulating layer 110 and covering at least a portion of the conductive pad 140, and a solder resist layer 160 disposed on the insulating layer 110 and covering at least a portion of each of the second conductive pattern 130, the conductive pad 140, and the conductive bump 150. The conductive bump 150 may have a maximum width greater than that of the conductive pad 140. The maximum width may be measured, for example, on a cross-sectional surface as described below.

In the printed circuit board 100A according to the example, a conductive bump 150 disposed on the insulating layer 110, spaced apart from the insulating layer 110 and covering at least a portion of the conductive pad 140 may be disposed, and at least a portion of the conductive pad 140 and at least a portion of the conductive bump 150 may be covered by the solder resist layer 160, and in this case, the conductive bump 150 may have a size greater than a size of the conductive pad 140. The conductive pad 140 and the conductive bump 150 configured as above may be easily applied to mounting of a high-performance die requiring high-density input/output terminals. For example, a level of the conductive bump 150 may be increased, which may be advantageous in ensuring a standoff level between the die and the substrate, and accordingly, it may be advantageous in improving connection reliability with the die and stability of the underfill formation. Also, the size of the conductive bump 150 may be increased separately from a design rule of the conductive pad 140, and accordingly, it may be more advantageous in ensuring connection strength of the die. Also, the size of the conductive pad 140 may be reduced, and accordingly, circuit density and circuit design freedom of the second conductive pattern 130 formed on the same layer may be improved. Also, due to this structure, the process of opening the solder resist layer 160 may not be performed, such that interfacial surface residue or footings occurring during the process of opening the solder resist layer 160 may be prevented, and accordingly, reliability of the conductive bump 150 may be improved.

At least a portion of the solder resist layer 160 may be disposed between an upper surface of the insulating layer 110 and a lower surface of the conductive bump 150, and a lower surface of the conductive bump 150 may be in contact with the solder resist layer 160. Also, the solder resist layer 160 may cover a portion of a side surface of the conductive pad 140, and the conductive bump 150 may cover an upper surface and the other portion of a side surface of the conductive pad 140. Also, the solder resist layer 160 may cover a portion of the side surface of the conductive bump 150, and an upper surface and the other portion of a side surface of the conductive bump 150 may protrude to the upper surface of the solder resist layer 160. Through this arrangement and structure, the level of the conductive bump 150 may be increased easily. Also, separately from a design rule of the conductive pad 140, the size of the conductive bump 150 may be increased easily. Also, the size of the conductive pad 140 may be easily reduced. Accordingly, the above-described effects may be easily implemented.

The conductive pad 140 may have a first side surface S1 and a second side surface S2 opposing each other, and the conductive bump 150 may have a third side surface S3 and a fourth side surface S4 opposing each other, and the third side surface S3 and the fourth side surface S4 of the conductive bump 150 may protrude toward an outer side of the first side surface S1 and the second side surface S2 of the conductive pad 140, respectively. For example, the third side surface S3 of the conductive bump 150 may protrude in a direction perpendicular to the first side surface S1 of the conductive pad 140, and the fourth side surface S4 of the conductive bump 150 may protrude in a direction perpendicular to the second side surface S2 of the conductive pad 140. In this case, a protruded length L1 of the third side surface S3 of the conductive bump 150 from the first side surface S1 of the conductive pad 140 and a protruded length L2 of the fourth side surface S4 of the conductive bump 150 from the second side surface S2 of the conductive pad 140 may be substantially the same. However, an embodiment thereof is not limited thereto, and if desired, the protruded lengths L1 and L2 may be different. For example, the protruded length L1 may be longer than the protruded length L2, or alternatively, the protruded length L2 may be longer than the protruded length L1. Through this protruding structure, separately from a design rule of the conductive pad 140, the size of the conductive bump 150 may be increased easily and the size of the conductive pad 140 may be easily reduced. Accordingly, the above-described effects may be easily implemented.

The conductive bump 150 may include a seed layer M1 and a metal layer M2 disposed on the seed layer M1. The seed layer M1 may be in contact with at least a portion of each of the conductive pad 140 and the solder resist layer 160. For example, the seed layer M1 may cover an upper end portion of the conductive pad 140 and may extend to the periphery thereof. The seed layer M1 may be formed by electroless plating and may include, for example, chemical copper. The metal layer M2 may be formed by electrolytic plating and may include, for example, electrolytic copper. However, an embodiment thereof is not limited thereto. By forming the conductive bump 150 by a plating process using circuit lithography as above, separately from a design rule of the conductive pad 140, the size of the conductive bump 150 may be easily determined. Also, in connection with the conductive pad 140, bonding between the same metals, for example, bonding between copper (Cu) and copper (Cu), may be performed, and accordingly, greater bonding strength may be obtained. At least a portion of the side surface of the seed layer M1 may be recessed toward the inner side relative to the side surface of the metal layer M2. In this case, the solder resist layer 160 may fill the recessed space, and accordingly, may bonding reliability may further improve. However, an embodiment thereof is not limited thereto, and if desired, the side surface of the seed layer M1 may not be recessed. For example, the side surface of the seed layer M1 and the side surface of the metal layer M2 may be substantially coplanar with each other.

The solder resist layer 160 may include first and second solder resist layers 161 and 162. A first solder resist layer 161 may be disposed on the insulating layer 110 and may cover a portion of a side surface of each of the second conductive pattern 130 and the conductive pad 140. The second solder resist layer 162 may be disposed on the first solder resist layer 161 and may cover an upper surface and the other portion of a side surface of the second conductive pattern 130, and may also cover a portion of the side surface of the conductive bump 150. The first solder resist layer 161 may have a thickness less than a thickness of the second conductive pattern 130 and/or the conductive pad 140. Accordingly, a portion of the second conductive pattern 130 and/or the conductive pad 140 may protrude to the upper surface of the first solder resist layer 161. The second solder resist layer 162 may have a thickness less than a thickness of the conductive bump 150. Accordingly, a portion of the conductive bump 150 may protrude to the upper surface of the second solder resist layer 162. When the solder resist layer 160 includes the first and second solder resist layers 161 and 162 having such a structure and arrangement, the conductive pad 140 and the conductive bump 150 may be easily implemented with the above-described structure. Accordingly, the above-described effect may be easily implemented. The first and second solder resist layers 161 and 162 may include substantially the same insulating material, and accordingly, the first and second solder resist layers 161 and 162 may be integrated with each other such that a boundary therebetween may not be distinct, but an embodiment thereof is not limited thereto, and the first and second solder resist layers 161 and 162 may include different insulating materials or the boundaries may be distinct from each other for other reasons.

The insulating layer 110 may have a conductive via connected to at least a portion of the first conductive pattern 120 if desired, and even in this case, the conductive pad 140 may not be directly connected to the conductive via formed in the insulating layer 110. For example, the conductive pad 140 may have a via-unconnected pad structure. For example, a lower surface of the conductive pad 140 may be entirely in contact with the insulating layer 110. In this case, a size of the conductive pad 140 may be further reduced. When the size of the conductive pad 140 may be further reduced as above, a line width of the conductive line passing around the conductive pad 140 among the conductive lines included in the second conductive pattern 130 may further increase. Accordingly, circuit design freedom of the second conductive pattern 130 may be increased. Also, when a plurality of the conductive pads 140 and a plurality of the corresponding conductive bumps 150 are formed, a pitch of the conductive bump 150 may be implemented as a finer pitch.

Hereinafter, the components of the printed circuit board 100A according to an example may be described in greater detail with reference to the diagram.

The insulating layer 110 may include an insulating material. As the insulating material, a thermosetting resin such as an epoxy resin, a thermoplastic resin such as a polyimide, or a material in which these insulating resins are mixed with an inorganic filler such as silica, or a resin impregnated into a core material such as glass fiber together with an inorganic filler, for example, an insulating material such as prepreg, Ajinomoto build-up film (ABF), photoimageable dielectric (PID), and resin coated copper (RCC), or the like, may be used, but an embodiment thereof is not limited thereto. The insulating layer 110 may include a plurality of layers if desired. The plurality of layers may include substantially the same insulating material, and a boundary therebetween may be indistinct, but a boundary may be distinct. Also, the plurality of layers may include different insulating materials.

Each of the first and second conductive patterns 120 and 130 may include a metal. The metal may include copper (Cu), aluminum (Al), silver (Ag), tin (Sn), gold (Au), nickel (Ni), lead (Pb), titanium (Ti), and/or alloys thereof. For example, each of the first and second conductive patterns 120 and 130 may include chemical copper formed by electroless plating as a seed layer, and may include electrolytic copper formed by electrolytic plating based on chemical copper as a plating layer, but an embodiment thereof is not limited thereto. If desired, sputtered titanium and/or sputtered copper formed by sputtering may be included as a seed layer, or the material may be further included together with chemical copper. Each of the first and second conductive patterns 120 and 130 may perform various functions depending on a design. For example, each of the first and second conductive patterns 120 and 130 may include a signal transmission pattern, a power transmission pattern, a ground transmission pattern, or the like. These patterns may have various pattern shapes such as a line, a trace, a plane, a pad, and a land.

The conductive pad 140 may include a metal. The metal may include copper (Cu), aluminum (Al), silver (Ag), tin (Sn), gold (Au), nickel (Ni), lead (Pb), titanium (Ti), and/or alloys thereof. For example, the conductive pad 140 may include chemical copper formed by electroless plating as a seed layer, and may include electrolytic copper formed by electrolytic plating based on this as a plating layer, but an embodiment thereof is not limited thereto. If desired, sputtered titanium and/or sputtered copper formed by sputtering may be included as a seed layer, or these may be further included together with chemical copper. The conductive pad 140 may perform various functions depending on a design. For example, the conductive pad 140 may include a signal transmission pad, a power transmission pad, a ground transmission pad, or the like. The conductive pad 140 may have a circular or elliptical shape on a plane, but an embodiment thereof is not limited thereto, and the conductive pad 140 may also have various types of polygonal shapes. The conductive pad 140 may be connected to at least a portion of the second conductive pattern 130, such as a conductive line of the second conductive pattern 130. The conductive pad 145 may have a side surface substantially vertical, but an embodiment thereof is not limited thereto. A plurality of the conductive pads 140 may be provided.

The conductive bump 150 may include a metal. The metal may include copper (Cu), aluminum (Al), silver (Ag), tin (Sn), gold (Au), nickel (Ni), lead (Pb), titanium (Ti), and/or alloys thereof. For example, the conductive bump 150 may include chemical copper formed by electroless plating as a seed layer, and may include electrolytic copper formed by electrolytic plating as a plating layer based on this, but an embodiment thereof is not limited thereto. If desired, the seed layer may include sputtered titanium and/or sputtered copper formed by sputtering, or may further include these together with chemical copper. The conductive bump 150 may perform various functions depending on a design. For example, the conductive bump 150 may include a signal transmission bump, a power transmission bump, a ground transmission bump, or the like. The conductive bump 150 may have a circular or elliptical shape on a plane, but an embodiment thereof is not limited thereto, and the conductive bump 150 may have various types of polygonal shapes. The conductive bump 150 may have a side surface substantially vertical, but an embodiment thereof is not limited thereto. The conductive bump 150 may substantially cover an upper end portion of the conductive pad 140 in a hat shape, but an embodiment thereof is not limited thereto. The edge portion and the corner portion of the upper surface of the conductive bump 150 may have a substantially vertical shape, but an embodiment thereof is not limited thereto, and the edge portion and the corner portion may have a substantially rounded shape. When a plurality of the conductive pads 140 are provided, a plurality of the conductive bump 150 may be provided.

Each of the first and second solder resist layers 161 and 162 may include an insulating material. The insulating material may include a thermosetting resin such as an epoxy resin, a thermoplastic resin such as a polyimide, or an inorganic filler and/or an organic filler together with the resin. For example, each of the first and second solder resist layers 161 and 162 may include Ajinomoto build-up film (ABF), solder resist (SR), or the like, but an embodiment thereof is not limited thereto. Each of the first and second solder resist layers 161 and 162 may be a liquid type or a film type, but an embodiment thereof is not limited thereto. The first and second solder resist layers 161 and 162 may include substantially the same insulating material, but an embodiment thereof is not limited thereto, and the first and second solder resist layers 161 and 162 may include different insulating materials.

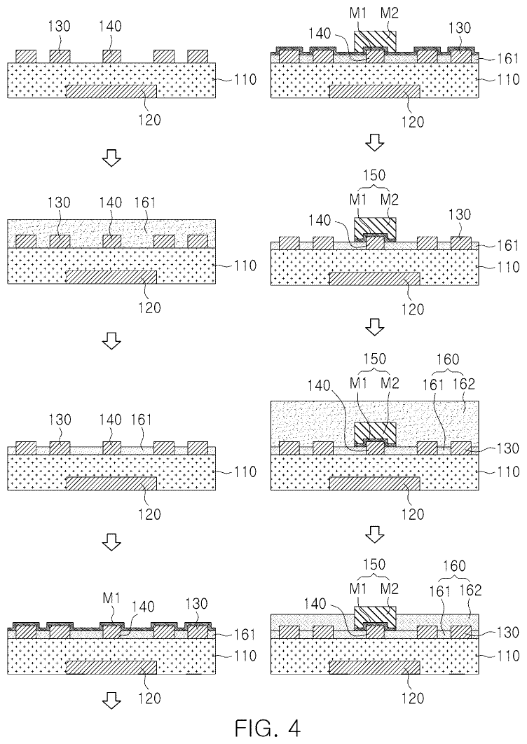

FIG. 4 is a process diagram illustrating an example of manufacturing the printed circuit board illustrated in FIG. 3 according an example embodiment.

Referring to the diagram, a method of manufacturing a printed circuit board 100A according to an example may include forming a first conductive pattern 120 in an insulating layer 110, forming a second conductive pattern 130 and a conductive pad 140 on the insulating layer 110, forming a first solder resist layer 161 covering the conductive pad 140 on the insulating layer 110, exposing a portion of the conductive pad 140 from the first solder resist layer 161 by reducing a thickness of the first solder resist layer 161, forming a conductive bump 150 covering an exposed portion of the conductive pad 140 on the first solder resist layer 161, forming a second solder resist layer 162 covering the conductive bump 150 on the first solder resist layer 161, and exposing a portion of the conductive bump 150 from the second solder resist layer 162 by reducing a thickness of the second solder resist layer 162. The forming the conductive bump 150 may include forming the conductive bump 150 such that the conductive bump 150 may have a maximum width greater than that of the conductive pad 140. The formed first and second solder resist layers 161 and 162 may be included in the solder resist layer 160. The maximum width may be measured, for example, on a cross-sectional surface as described below.

The method of manufacturing the printed circuit board according to an example may include forming the first solder resist layer 161 covering the conductive pad 140 on the insulating layer 110, and exposing a portion of the conductive pad 140 by reducing the thickness of the first solder resist layer 161, and a portion of the exposed conductive pad 140 may be covered with the conductive pad 150 having a greater size. Also, after forming the second solder resist layer 162 covering the conductive bump 150, by reducing the thickness of the second solder resist layer 162, a portion of the conductive bump 150 may be exposed. Accordingly, a level of the conductive bump 150 may be easily increased, which may be advantageous for ensuring the standoff level between the die and the substrate, and accordingly, connection reliability with the die and stability of the underfill formation may improve. Also, the size of the conductive bump 150 may be increased separately from a design rule of the conductive pad 140, which may be advantageous for ensuring connection strength of the die. Also, the size of the conductive pad 140 may be reduced, and accordingly, circuit density and circuit design freedom of the second conductive pattern 130 formed on the same layer may be improved.

The forming the conductive bump 150 may include forming a seed layer M1 on an upper surface of the first solder resist layer 161 and an upper surface and a side surfaces of an exposed portion of each of the second conductive pattern 130 and the conductive pad 140, forming a plating layer M2 on a region corresponding to the conductive pad 140 on the seed layer M1 by circuit lithography and electrolytic plating, and removing the seed layer M1 in a region of the upper surface of the first solder resist layer 161, in which the plating layer M2 is not formed, by etching. The seed layer M1 may be formed by electroless plating and may include, for example, chemical copper. The metal layer M2 may be formed by electrolytic plating and may include, for example, electrolytic copper. However, an embodiment thereof is not limited thereto. By forming the conductive bump 150 by a plating process using circuit lithography as above, the size of the conductive bump 150 may be easily determined separately from a design rule of the conductive pad 140. Also, as for connection with the conductive pad 140, bonding between the same metals, for example, bonding between copper (Cu) and copper (Cu), may be performed, and accordingly, greater bonding strength may be obtained. In the removing the seed layer M1 by etching, at least a portion of the side surface of the seed layer M1 below the plating layer M2 may be removed by flash etching, or the like, and accordingly, a recessed space may be formed. In this case, the solder resist layer 160 may fill the recessed space, and accordingly, bonding reliability may be further improved. However, an embodiment thereof is not limited thereto, and if desired, the side surface of the seed layer M1 may not be recessed. For example, the side surface of the seed layer M1 and the side surface of the metal layer M2 may be substantially coplanar with each other. Also, in removing the seed layer M1 by etching, if desired, at least a portion of the second conductive pattern 130 may be removed. Accordingly, the thickness of the conductive pad 140 may be greater than the thickness of the second conductive pattern 130.

The forming the second conductive pattern 130 and the conductive pad 140 may further include, if desired, forming a conductive via penetrating at least a portion of the insulating layer 110 and connected to at least a portion of the first conductive pattern 120. For example, the conductive via may be formed by forming a via hole in the insulating layer 110 and filling at least a portion of the via hole by plating. In this case, the conductive pad 140 may not be directly connected to the conductive via formed in the insulating layer 110. For example, the conductive pad 140 may be formed as a via-unconnected pad structure. In this case, the size of the conductive pad 140 may be further reduced. When the size of the conductive pad 140 may be further reduced, the line width of the conductive line passing around the conductive pad 140 among the conductive lines included in the second conductive pattern 130 may further increase. Accordingly, circuit design freedom of the second conductive pattern 130 may be increased. Also, in the case in which a plurality of the conductive pad 140 and a plurality of the corresponding conductive bump 150 are formed, the pitch of the conductive bump 150 may be implemented as a finer pitch.

Other descriptions may be substantially the same as the description of the printed circuit board 100A described above, and overlapping descriptions will not be provided.

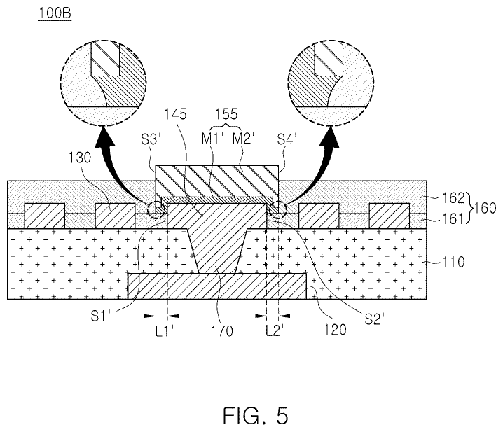

FIG. 5 is a cross-sectional diagram illustrating another example of a printed circuit board according an example embodiment.

Referring to the diagram, a printed circuit board 100B according to another example may include an insulating layer 110, a first conductive pattern 120 disposed in the insulating layer 110, a second conductive pattern 130 and a conductive pad 145 disposed on the insulating layer 110, a conductive bump 155 disposed on the insulating layer 110, spaced apart from the insulating layer 110 and covering at least a portion of the conductive pad 145, a solder resist layer 160 disposed on the insulating layer 110 and covering at least a portion of each of the second conductive pattern 130, the conductive pad 145, and the conductive bump 155, and a conductive via 170 penetrating at least a portion of the insulating layer 110 and connecting the first conductive pattern 120 to the conductive pad 145. The conductive bump 150 may have a maximum width greater than that of the conductive pad 145. The maximum width may be measured, for example, on a cross-sectional surface as described below.

The printed circuit board 100B according to another example may have a conductive bump 155 disposed on an insulating layer 110, spaced apart from the insulating layer 110 and covering at least a portion of the conductive pad 145, and at least a portion of each of the conductive pad 145 and the conductive bump 155 may be covered by a solder resist layer 160, and in this case, the conductive bump 155 may be formed to have a size greater than a size of the conductive pad 145. The conductive pad 145 and the conductive bump 155 having this structure may be easily applied to mounting of a high-performance die requiring high-density input/output terminals. For example, the level of the conductive bump 155 may be increased, which may be advantageous in ensuring a standoff level between the die and the substrate, and accordingly, connection reliability with the die and stability of underfill formation may improve. Also, the size of the conductive bump 155 may be increased separately from a design rule of the conductive pad 145, which may be more advantageous in ensuring connection strength of the die. Also, the size of the conductive pad 145 may be reduced, and accordingly, circuit density and circuit design freedom of the second conductive pattern 130 formed on the same layer may be improved. Also, the process of opening the solder resist layer 160 may not performed for this structure, and interfacial surface residue or footing occurring during the process of opening the solder resist layer 160 may be prevented, and accordingly, reliability of the conductive bump 155 may be improved.

At least a portion of the solder resist layer 160 may be disposed between an upper surface of the insulating layer 110 and a lower surface of the conductive bump 155, and the lower surface of the conductive bump 155 may be in contact with the solder resist layer 160. Also, the solder resist layer 160 may cover a portion of the side surface of the conductive pad 145, and the conductive bump 155 may cover an upper surface and the other portion of a side surface of the conductive pad 145. Also, the solder resist layer 160 may cover a portion of the side surface of the conductive bump 155, and an upper surface and the other portion of a side surface of the conductive bump 155 may protrude to the upper surface of the solder resist layer 160. Through this arrangement and structure, the level of the conductive bump 155 may be increased easily. Also, the size of the conductive bump 155 may be increased easily separately from a design rule of the conductive pad 145. Also, the size of the conductive pad 145 may be easily reduced. Accordingly, the above-described effects may be easily implemented.

The conductive pad 145 may have a first side surface S1′ and a second side surface S2′ opposing each other, and the conductive bump 155 may have a third side surface S3′ and a fourth side surface S4′ opposing each other, and the third side surface S3′ and the fourth side surface S4′ of the conductive bump 155 may protrude toward an outer side relative to the first side surface S1′ and the second side surface S2′ of the conductive pad 145, respectively. For example, the third side surface S3′ of the conductive bump 155 may protrude in a direction perpendicular to the first side surface S1′ of the conductive pad 145, and the fourth side surface S4′ of the conductive bump 155 may protrude in a direction perpendicular to the second side surface S2′ of the conductive pad 145. In this case, the protruding length L1′ of the third side surface S3′ of the conductive bump 155 from the first side surface S1′ of the conductive pad 145 and the protruding length L2′ of the fourth side surface S4′ of the conductive bump 155 from the second side surface S2′ of the conductive pad 145 may be substantially the same. However, an embodiment thereof is not limited thereto, and if desired, the protruding lengths L1′ and L2′ may be different. For example, the protruding length L1′ may be longer than the protruding length L2′, or alternatively, the protruding length L2′ may be longer than the protruding length L1′. Through this protruding structure, the size of the conductive bump 155 may be increased easily and the size of the conductive pad 145 may be easily reduced separately from a design rule of the conductive pad 145. Accordingly, the above-described effects may be easily implemented.

The conductive bump 155 may include a seed layer M1′ and a metal layer M2′ disposed on the seed layer M1′. The seed layer M1′ may be in contact with at least a portion of each of the conductive pad 145 and the solder resist layer 160. For example, the seed layer M1′ may cover an upper end portion of the conductive pad 145 and may extend to the periphery thereof. The seed layer M1′ may be formed by electroless plating and may include, for example, chemical copper. The metal layer M2′ may be formed by electrolytic plating and may include, for example, electrolytic copper. However, an embodiment thereof is not limited thereto. By forming the conductive bump 155 by a plating process using circuit lithography as above, the size of the conductive bump 155 may be easily determined separately from a design rule of the conductive pad 145. Also, in connection with the conductive pad 145, bonding between the same metals, for example, bonding between copper (Cu) and copper (Cu), may be performed, and accordingly, greater bonding strength may be obtained. At least a portion of the side surface of the seed layer M1′ may be recessed toward an inner side relative to the side surface of the metal layer M2. In this case, the solder resist layer 160 may fill the recessed space, and accordingly, bonding reliability may further improve. However, an embodiment thereof is not limited thereto, and if desired, the side surface of the seed layer M1′ may not be recessed. For example, the side surface of the seed layer M1′ and the side surface of the metal layer M2 may be substantially coplanar with each other.

The solder resist layer 160 may include first and second solder resist layers 161 and 162. A first solder resist layer 161 may be disposed on the insulating layer 110 and may cover a portion of a side surface of each of the second conductive pattern 130 and the conductive pad 145. The second solder resist layer 162 may be disposed on the first solder resist layer 161 and may cover an upper surface and the other portion of a side surface of the second conductive pattern 130, and may also cover a portion of the side surface of the conductive bump 155. The first solder resist layer 161 may have a thickness less than a thickness of the second conductive pattern 130 and/or the conductive pad 145. Accordingly, a portion of the second conductive pattern 130 and/or the conductive pad 145 may protrude to the upper surface of the first solder resist layer 161. The second solder resist layer 162 may have a thickness less than a thickness of the conductive bump 155. Accordingly, a portion of the conductive bump 155 may protrude to the upper surface of the second solder resist layer 162. When the solder resist layer 160 includes the first and second solder resist layers 161 and 162 having such a structure and arrangement, the conductive pad 145 and the conductive bump 155 may be easily implemented with the above-described structure. Accordingly, the above-described effect may be easily implemented. The first and second solder resist layers 161 and 162 may include substantially the same insulating material, and accordingly, the first and second solder resist layers 161 and 162 may be integrated with each other such that a boundary therebetween may not be distinct, but an embodiment thereof is not limited thereto, and the first and second solder resist layers 161 and 162 may include different insulating materials or a boundary therebetween may be distinct for other reasons.

The conductive via 170 may be directly connected to the conductive pad 145. For example, the conductive pad 145 may have a via connection pad structure. For example, at least a portion of the lower surface of the conductive pad 145 may be in contact with the insulating layer 110, and at least the other portion of the lower surface may be in contact with the conductive via 170. In this case, the size of the conductive pad 145 may be increased, and accordingly, adhesion to the conductive bump 155 may be improved. A plurality of the conductive pad 145, a plurality of the corresponding conductive bumps 150 and plurality of the conductive via 170 may be disposed.

Hereinafter, components of the printed circuit board 100B according to another example will be described in greater detail with reference to the diagram.

The insulating layer 110 may include an insulating material. As the insulating material, a thermosetting resin such as an epoxy resin, a thermoplastic resin such as a polyimide, or a material in which these insulating resins are mixed with an inorganic filler such as silica, or a resin impregnated into a core material such as glass fiber together with an inorganic filler, for example, an insulating material such as prepreg, Ajinomoto build-up film (ABF), photo image-able dielectric (PID), and resin coated copper (RCC), or the like, may be used, but an embodiment thereof is not limited thereto. The insulating layer 110 may include a plurality of layers if desired. The plurality of layers may include substantially the same insulating material, and a boundary therebetween may be indistinct, but a boundary may be distinct. Also, the plurality of layers may include different insulating materials.

Each of the first and second conductive patterns 120 and 130 may include a metal. The metal may include copper (Cu), aluminum (Al), silver (Ag), tin (Sn), gold (Au), nickel (Ni), lead (Pb), titanium (Ti), and/or alloys thereof. For example, each of the first and second conductive patterns 120 and 130 may include chemical copper formed by electroless plating as a seed layer, and may include electrolytic copper formed by electrolytic plating based on chemical copper as a plating layer, but an embodiment thereof is not limited thereto. If desired, sputtered titanium and/or sputtered copper formed by sputtering may be included as the seed layer, or these may be further included together with chemical copper. Each of the first and second conductive patterns 120 and 130 may perform various functions depending on a design. For example, each of the first and second conductive patterns 120 and 130 may include a signal transmission pattern, a power transmission pattern, a ground transmission pattern, or the like. These patterns may have various pattern shapes such as a line, a trace, a plane, a pad, and a land.

The conductive pad 145 may include a metal. The metal may include copper (Cu), aluminum (Al), silver (Ag), tin (Sn), gold (Au), nickel (Ni), lead (Pb), titanium (Ti), and/or alloys thereof. For example, the conductive pad 145 may include chemical copper formed by electroless plating as a seed layer, and may include electrolytic copper formed by electrolytic plating based on this as a plating layer, but an embodiment thereof is not limited thereto. If desired, sputtered titanium and/or sputtered copper formed by sputtering may be included as a seed layer, or the material may be further included together with chemical copper. The conductive pad 145 may perform various functions depending on a design. For example, the conductive pad 145 may include a signal transmission pad, a power transmission pad, a ground transmission pad, or the like. The conductive pad 145 may have a circular or elliptical shape on a plane, but an embodiment thereof is not limited thereto, and the conductive pad 145 may also have various types of polygonal shapes. The conductive pad 145 may be connected to at least a portion of the second conductive pattern 130, such as a conductive line of the second conductive pattern 130. The conductive pad 145 may have a side surface substantially vertical, but an embodiment thereof is not limited thereto. A plurality of the conductive pad 145 may be provided.

The conductive bump 155 may include a metal. The metal may include copper (Cu), aluminum (Al), silver (Ag), tin (Sn), gold (Au), nickel (Ni), lead (Pb), titanium (Ti), and/or alloys thereof. For example, the conductive bump 155 may include chemical copper formed by electroless plating as a seed layer, and may include electrolytic copper formed by electrolytic plating as a plating layer based on this, but an embodiment thereof is not limited thereto. If desired, the seed layer may include sputtered titanium and/or sputtered copper formed by sputtering, or may further include these together with chemical copper. The conductive bump 155 may perform various functions depending on a design. For example, the conductive bump 155 may include a signal transmission bump, a power transmission bump, a ground transmission bump, or the like. The conductive bump 155 may have a circular or elliptical shape on a plane, but an embodiment thereof is not limited thereto, and may have various types of polygonal shapes. The conductive bump 155 may have a side surface substantially vertical, but an embodiment thereof is not limited thereto. The conductive bump 155 may substantially cover the upper end portion of the conductive pad 145 in a hat shape, but an embodiment thereof is not limited thereto. The edge portion and the corner portion of the upper surface of the conductive bump 155 may substantially have a vertical shape, but an embodiment thereof is not limited thereto, and the edge portion and the corner portion may substantially have a rounded shape. When the plurality of conductive pads 145 are provided, the plurality of the conductive bump 155 may be provided.

Each of the first and second solder resist layers 161 and 162 may include an insulating material. The insulating material may include a thermosetting resin such as an epoxy resin, a thermoplastic resin such as a polyimide, or an inorganic filler and/or an organic filler together with the resin. For example, each of the first and second solder resist layers 161 and 162 may include Ajinomoto build-up film (ABF), solder resist (SR), or the like, but an embodiment thereof is not limited thereto. Each of the first and second solder resist layers 161 and 162 may be a liquid type or a film type, but an embodiment thereof is not limited thereto. The first and second solder resist layers 161 and 162 may include substantially the same insulating material, but an embodiment thereof is not limited thereto, and the first and second solder resist layers 161 and 162 may include different insulating materials.

The conductive via 170 may include a metal. The metal may include copper (Cu), aluminum (Al), silver (Ag), tin (Sn), gold (Au), nickel (Ni), lead (Pb), titanium (Ti), and/or alloys thereof. For example, the conductive via 170 may include electroless-plated chemical copper as a seed layer, and electrolytic copper formed by electrolytic plating as a plating layer based on the electroless-plated chemical copper, but an embodiment thereof is not limited thereto. If desired, the seed layer may include sputtered titanium and/or sputtered copper formed by sputtering, or may further include these together with chemical copper. The conductive via 170 may include a signal transmission via, a power transmission via, a ground transmission via, or the like. The conductive via 170 may have a substantially tapered side surface in which an upper end portion may have a width greater than that of a lower end portion. The conductive via 170 may have a fill-plated via structure. A plurality of the conductive via 170 may be provided, and if desired, at least a portion of the conductive via 170 may be connected to at least a portion of the second conductive pattern 130.

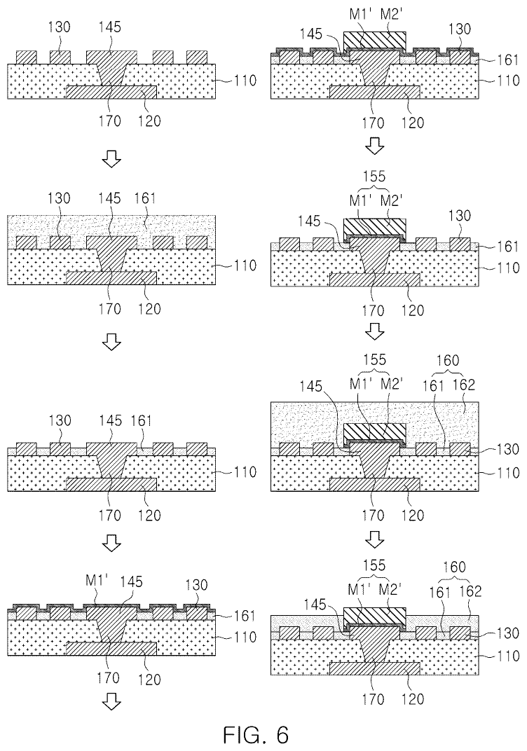

FIG. 6 is a process diagram illustrating an example of manufacturing the printed circuit board illustrated in FIG. 5 according an example embodiment.

Referring to the diagram, a method of manufacturing the printed circuit board 100B according to another example may include forming a first conductive pattern 120 in an insulating layer 110, forming a second conductive pattern 130 and a conductive pad 145 on the insulating layer 110, forming a conductive via 170 penetrating at least a portion of the insulating layer 110 and connecting the first conductive pattern 120 to the conductive pad 145, forming a first solder resist layer 161 covering the conductive pad 145 on the insulating layer 110, exposing a portion of the conductive pad 145 from the first solder resist layer 161 by reducing a thickness of the first solder resist layer 161, forming a conductive bump 155 covering an exposed portion of the conductive pad 145 on the first solder resist layer 161, forming a second solder resist layer 162 covering the conductive bump 155 on the first solder resist layer 161, and exposing a portion of the conductive bump 155 from the second solder resist layer 162 by reducing the thickness of the second solder resist layer 162. The forming the conductive bump 155 may include forming the conductive bump 155 such that a maximum width of the conductive bump 155 may be greater than that of the conductive pad 145. The formed first and second solder resist layers 161 and 162 may be included in the solder resist layer 160. The maximum width may be measured, for example, on a cross-sectional surface as described below.

The method of manufacturing the printed circuit board according to another example may include forming a first solder resist layer 161 covering a conductive pad 145 on an insulating layer 110, and exposing a portion of the conductive pad 145 by reducing the thickness of the first solder resist layer 161, and may cover the exposed portion of the conductive pad 145 with a conductive bump 155 having a greater size. Also, after forming the second solder resist layer 162 covering the conductive bump 155, by reducing the thickness of the second solder resist layer 162, a portion of the conductive bump 155 may be exposed. Accordingly, the level of the conductive bump 155 may be easily increased, which may be advantageous in ensuring the standoff level between the die and the substrate, and accordingly, connection reliability with the die and stability of underfill formation may improve. Also, the size of the conductive bump 155 may be increased separately from a design rule of the conductive pad 145, which may be advantageous in ensuring connection strength of the die. Also, the size of the conductive pad 145 may be reduced, and accordingly, circuit density and circuit design freedom of the second conductive pattern 130 formed on the same layer may be improved.

Forming the conductive bump 155 may include forming a seed layer M1′ on an upper surface of a first solder resist layer 161 and an upper surface and side surfaces of an exposed portion of each of the second conductive pattern 130 and the conductive pad 145, forming a plating layer M2′ on a region corresponding to the conductive pad 145 on the seed layer M1′ by circuit lithography and electrolytic plating, and removing the seed layer M1′ in a region of the upper surface of the first solder resist layer 161, in which the plating layer M2′ is not formed, by etching. The seed layer M1′ may be formed by electroless plating and may include, for example, chemical copper. The metal layer M2′ may be formed by electrolytic plating and may include, for example, electrolytic copper. However, an embodiment thereof is not limited thereto. By forming the conductive bump 155 by a plating process using circuit lithography as above, the size of the conductive bump 155 may be easily determined separately from a design rule of the conductive pad 145. Also, in connection with the conductive pad 145, bonding between the same metals, for example, bonding between copper (Cu) and copper (Cu), may be performed, and accordingly, greater bonding strength may be obtained. When removing the seed layer M1′ by etching, at least a portion of the side surface of the seed layer M1′ below the plating layer M2′ may be removed by flash etching, or the like, and accordingly, a recessed space may be formed. In this case, the solder resist layer 160 may fill the recessed space, and accordingly, bonding reliability may be further improved. However, an embodiment thereof is not limited thereto, and if desired, the side surface of the seed layer M1′ may not be recessed. For example, the side surface of the seed layer M1′ and the side surface of the metal layer M2′ may be substantially coplanar with each other. Also, in removing the seed layer M1′ by etching, if desired, at least a portion of the second conductive pattern 130 may be removed. Accordingly, the thickness of the conductive pad 145 may be greater than the thickness of the second conductive pattern 130.

In forming the conductive via 170, the conductive via 170 may be directly connected to the conductive pad 145. For example, the conductive pad 145 may be formed as a via connection pad structure. In this case, the size of the conductive pad 145 may increase, and accordingly, adhesion to the conductive pad 155 may be improved. A plurality of the conductive pad 145, a plurality of the corresponding conductive bump 155 and a plurality of the conductive via 170 may be formed.

Other descriptions may be substantially the same as the description of the above-described printed circuit board 100B, and overlapping descriptions will not be provided.

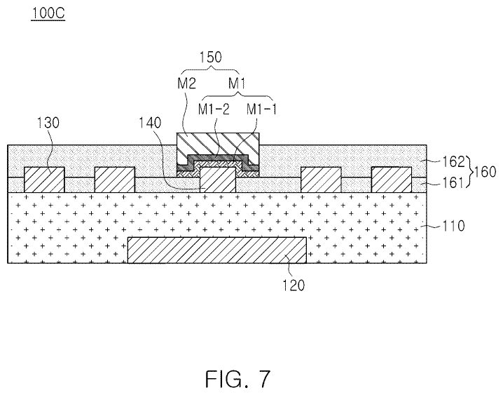

FIG. 7 is a cross-sectional diagram illustrating another example of a printed circuit board according an example embodiment.

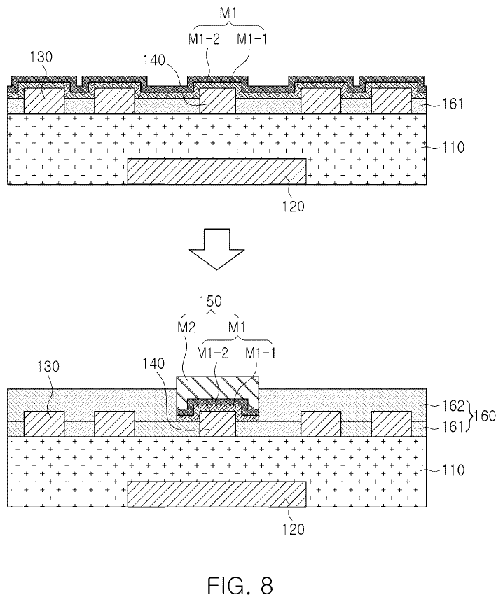

FIG. 8 is a process diagram illustrating an example of manufacturing the printed circuit board illustrated in FIG. 7 according an example embodiment.

Referring to the diagram, differently from the printed circuit board 100A according to the above-described example, a printed circuit board 100C according to another example may include a seed layer M1 of a conductive bump 150 including a plurality of seed layers M1-1 and M1-2. Also, differently from the method of manufacturing a printed circuit board 100A, a method of manufacturing the printed circuit board 100C according to another example may include forming a seed layer M1 according to the above-described example. At least one of the plurality of seed layers M1-1 and M1-2 may include a metal different from the metal layer M2. For example, the plurality of seed layers M1-1 and M1-2 may be formed by sputtering, and in this case, the first seed layer M1-1 of the plurality of seed layers M1-1 and M1-2 may include sputtered titanium, and also, the second seed layer M1-2 of the plurality of seed layers M1-1 and M1-2 may include sputtered copper. Also, the metal layer M2 may be formed by electrolytic plating as described above, and accordingly, the metal layer M2 may include electrolytic copper. The first seed layer M1-1 including a metal different from copper, for example, sputtered titanium, may be applied to the etched surface of the first solder resist layer 161, thereby improving adhesion strength. If desired, additional electroless plating may be performed on the second seed layer M1-2, and also, chemical copper may be formed on the sputtered copper.

Other descriptions may be substantially the same as the description of the printed circuit board 100A and the method of manufacturing the same described above, and overlapping descriptions will not be provided.

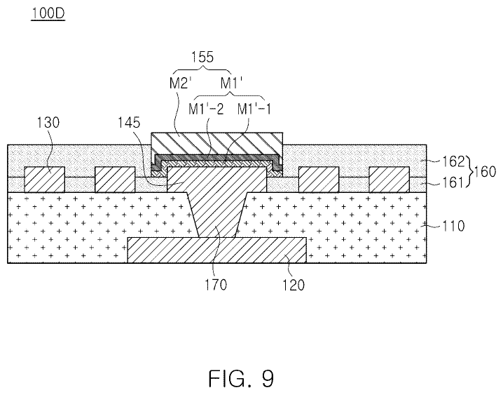

FIG. 9 is a cross-sectional diagram illustrating another example of a printed circuit board according an example embodiment.

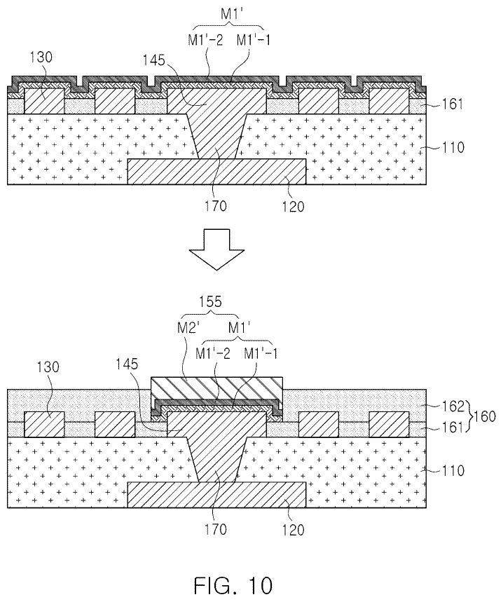

FIG. 10 is a process diagram illustrating an example of manufacturing the printed circuit board illustrated in FIG. 9 according an example embodiment.

Referring to the diagram, differently from the printed circuit board 100B according to another example described above, in a printed circuit board 100D according to another example, a seed layer M1′ of the conductive bump 155 may include a plurality of seed layers M1′-1 and M1′-2. Also, differently from the method of manufacturing the printed circuit board 100B according to another example described above, in the method of manufacturing the printed circuit board 100D according to another example, forming the seed layer M1′ may include forming a plurality of seed layers M1′-1 and M1′-2. At least one of the plurality of seed layers M1′-1 and M1′-2 may include a metal different from the metal layer M2′. For example, the plurality of seed layers M1′-1 and M1′-2 may be formed by sputtering, and in this case, the first seed layer M1′-1 among the plurality of seed layers M1′-1 and M1′-2 may include sputtered titanium, and also, the second seed layer M1′-2 among the plurality of seed layers M1′-1 and M1′-2 may include sputtered copper. Also, the metal layer M2′ may be formed by electrolytic plating as described above, and accordingly, the metal layer M2′ may include electrolytic copper. The first seed layer M1′-1 including a metal different from copper, for example, sputtered titanium, may be applied to the etched surface of the first solder resist layer 161 such that adhesion strength may improve. If desired, additional electroless plating may be performed on the second seed layer M1′-2, and chemical copper may be further formed on the sputtered copper.

Other descriptions may be substantially the same as the description of the printed circuit board 100B and the method of manufacturing the same described above, and overlapping descriptions will not be provided.

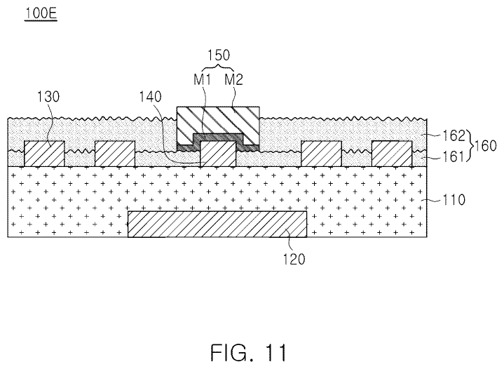

FIG. 11 is a cross-sectional diagram illustrating another example of a printed circuit board according to an example embodiment.

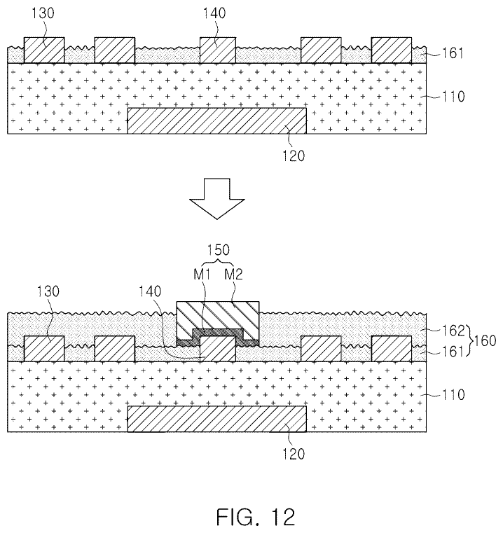

FIG. 12 is a process diagram illustrating an example of manufacturing the printed circuit board illustrated in FIG. 11 according an example embodiment.

Referring to the diagram, differently from the printed circuit board 100A according to the above-described example, in a printed circuit board 100E according to another example, roughness may be formed on an upper surface of a solder resist layer 160, and roughness may be formed on a boundary between the solder resist layer 160 and the lower surface of the conductive bump 150. Also, differently from the method of manufacturing a printed circuit board 100A according to the above-described example, the method of manufacturing a printed circuit board 100E according to another example may further include forming roughness on an upper surface of a solder resist layer 160 and forming roughness on a boundary between the solder resist layer 160 and a lower surface of a conductive bump 150. For example, the upper surface of the solder resist layer 160 may have surface roughness greater than that of a surface in contact with a side surface of a conductive pad 140 of the solder resist layer 160 and/or a surface in contact with a side surface of a conductive bump 150 of the solder resist layer 160. In this case, flowability and adhesion of the underfill may be improved during a package assembly process. Also, the surface in contact with the lower surface of the conductive bump 150 of the solder resist layer 160 may have surface roughness greater than that of the surface in contact with the side surface of the conductive pad 140 of the solder resist layer 160 and/or the surface in contact with the side surface of the conductive bump 150 of the solder resist layer 160. In this case, adhesion between the conductive bump 150 and the solder resist layer 160 may be more effective.

Roughness may also be formed on a boundary between the first and second solder resist layers 161 and 162. For example, the upper surface of the first solder resist layer 161 may have surface roughness greater than that of the surface in contact with the side surface of the conductive pad 140 of the first solder resist layer 161. In this case, adhesion between the first and second solder resist layers 161 and 162 may be improved. Even when the first and second solder resist layers 161 and 162 include substantially the same insulating material, the boundary between the first and second solder resist layers 161 and 162 may be distinct due to such roughness, but an embodiment thereof is not limited thereto, and the boundary may not be distinct depending on the size of the roughness or the characteristics of the material. Also, the upper surface of the second solder resist layer 162 providing the upper surface of the solder resist layer 160 may have surface roughness greater than that of the surface in contact with the side surface of the conductive bump 150 of the second solder resist layer 162. In this case, as described above, flowability and adhesion of the underfill may be improved during the package assembly process.

Reducing the thickness of the first solder resist layer 161 may include thinning the first solder resist layer 161 by etching. Also, reducing the thickness of the second solder resist layer 162 may include thinning the second solder resist layer 162 by etching. Here, the etching may be wet etching, but an embodiment thereof is not limited thereto, and the etching may be dry etching. In this case, surfaces of the first and second solder resist layers thinned by etching may have the roughness as described above. For example, the upper surface of the first solder resist layer 161 may have surface roughness greater than that of a surface in contact with the side surface of the conductive pad 140 of the first solder resist layer 161. In this case, as described above, adhesion of the first and second solder resist layers 161 and 162 may be improved. Also, the upper surface of the second solder resist layer 162 may have surface roughness greater than that of the surface in contact with the side surface of the conductive bump 150 of the second solder resist layer 162. In this case, as described above, flowability and adhesion of the underfill may be improved during the package assembly process.

The surface roughness may indicate average roughness Ra, and may be several microns to several tens of microns, but an embodiment thereof is not limited thereto.

Other descriptions may be substantially the same as the description of the printed circuit board 100A and the method of manufacturing the same described above, and overlapping descriptions will not be provided.

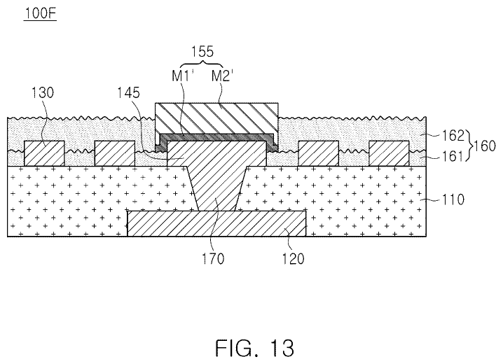

FIG. 13 is a cross-sectional diagram illustrating another example of a printed circuit board according to an example embodiment.

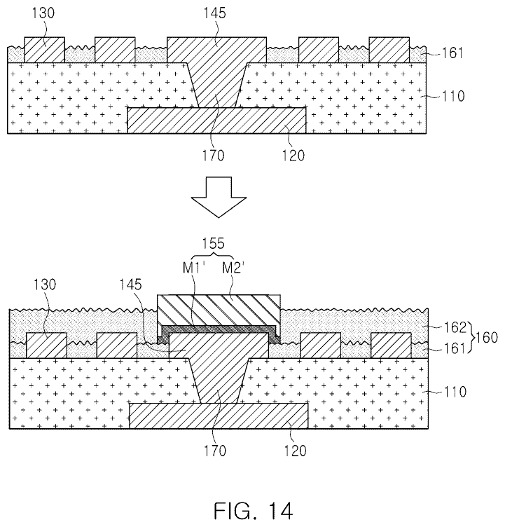

FIG. 14 is a process diagram illustrating an example of manufacturing the printed circuit board illustrated in FIG. 13 according to an example embodiment.

Referring to the diagram, differently from the printed circuit board 100B according to another example described above, in a printed circuit board 100F according to another example, roughness may be formed on an upper surface of a solder resist layer 160, and roughness may be formed on a boundary between the solder resist layer 160 and a lower surface of a conductive bump 155. Also, a method of manufacturing the printed circuit board 100F according to another example may further include forming roughness on an upper surface of the solder resist layer 160, and forming roughness on a boundary between the solder resist layer 160 and a lower surface of the conductive bump 155, differently from the method of manufacturing the printed circuit board 100B according to another example described above. For example, the upper surface of the solder resist layer 160 may have surface roughness greater than the surface in contact with the side surface of the conductive pad 145 of the solder resist layer 160 and/or the surface in contact with the side surface of the conductive bump 155 of the solder resist layer 160. In this case, flowability and adhesion of the underfill may be improved during the package assembly process. Also, the surface in contact with the lower surface of the conductive bump 155 of the solder resist layer 160 may have surface roughness greater than that of the surface in contact with the side surface of the conductive pad 145 of the solder resist layer 160 and/or the surface in contact with the side surface of the conductive bump 155 of the solder resist layer 160. In this case, adhesion between the conductive bump 155 and the solder resist layer 160 may be more effective.

Roughness may also be formed on a boundary between the first and second solder resist layers 161 and 162. For example, the upper surface of the first solder resist layer 161 may have surface roughness greater than that of the surface in contact with the side surface of the conductive pad 145 of the first solder resist layer 161. In this case, adhesion of the first and second solder resist layers 161 and 162 may be improved. Even when the first and second solder resist layers 161 and 162 include substantially the same insulating material, a boundary between the first and second solder resist layers 161 and 162 may be distinct due to the roughness, but an embodiment thereof is not limited thereto, and the boundary may not be distinct depending on the size of the roughness or the characteristics of the material. Also, the upper surface of the second solder resist layer 162 providing the upper surface of the solder resist layer 160 may have surface roughness greater than that of the surface in contact with the side surface of the conductive bump 155 of the second solder resist layer 162. In this case, as described above, flowability and adhesion of the underfill may be improved during the package assembly process.

The reducing the thickness of the first solder resist layer 161 may include thinning the first solder resist layer 161 by etching. Also, the reducing the thickness of the second solder resist layer 162 may include thinning the second solder resist layer 162 by etching. Here, the etching may be wet etching, but an embodiment thereof is not limited thereto, and the etching may also be dry etching. In this case, roughness may be formed on the surface thinned by etching of the first and second solder resist layers, as described below. For example, the upper surface of the first solder resist layer 161 may have surface roughness greater than that of the surface in contact with the side surface of the conductive pad 145 of the first solder resist layer 161. In this case, as described above, adhesion of the first and second solder resist layers 161 and 162 may be improved. Also, the upper surface of the second solder resist layer 162 may have surface roughness greater than that of the surface in contact with the side surface of the conductive bump 155 of the second solder resist layer 162. In this case, as described above, flowability and adhesion of the underfill may be improved during the package assembly process.

The surface roughness may indicate average roughness Ra, and may be several microns to several tens of microns, but an embodiment thereof is not limited thereto.

Other descriptions may be substantially the same as the description of the printed circuit board 100B and the method of manufacturing the same described above, and overlapping descriptions will not be provided.

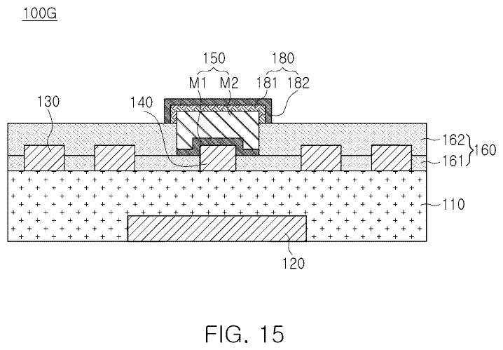

FIG. 15 is a cross-sectional diagram illustrating another example of a printed circuit board according to an example embodiment.

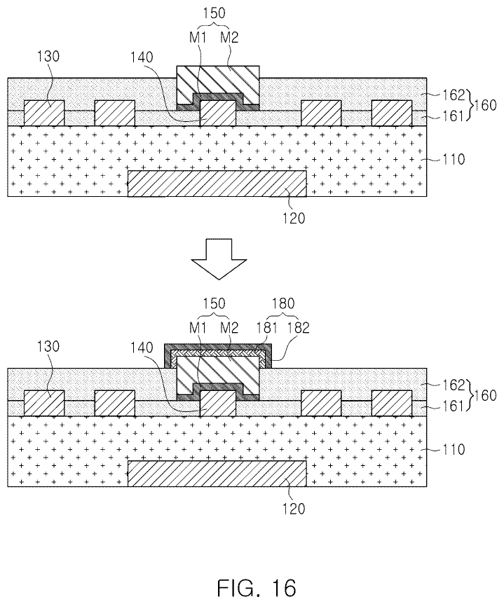

FIG. 16 is a process diagram illustrating an example of manufacturing the printed circuit board illustrated in FIG. 15 according to an example embodiment.

Referring to the diagram, differently from the printed circuit board 100A according to the above-described example, in a printed circuit board 100G according to another example, a surface treatment layer 180 may be disposed on a portion of the conductive bump 150 exposed from the solder resist layer 160, for example, the second solder resist layer 162. Also, the method of manufacturing the printed circuit board 100G according to another example may further include forming a surface treatment layer 180 on a portion of the conductive bump 150 exposed from a solder resist layer 160, for example, a second solder resist layer 162, differently from the method of manufacturing a printed circuit board 100A according to the above-described example. The surface treatment layer 180 may include a first surface treatment layer 181 disposed on an exposed portion of the conductive bump 150 and a second surface treatment layer 182 disposed on the first surface treatment layer 181. The first surface treatment layer 181 may include nickel (Ni), and the second surface treatment layer 182 may include gold (Au), but an embodiment thereof is not limited thereto, and various other materials may be used. The forming the surface treatment layer 180 may include, for example, an electroless nickel/immersion gold (ENIG), an electroless nickel/electroless palladium/immersion gold (ENEPIG), and/or an electrolytic nickel/gold plating (ENGP) process, but an embodiment thereof is not limited thereto, and hot air solder leveling (HASL), immersion silver (ImAg), and/or immersion tin (ImSn) processes may be included, and organic solderability preservative (OSP) process may be included, if desired. When the surface treatment layer 180 is formed, reliability may be ensured during die bonding in the packaging step. Also, copper consumption may be prevented.

Other descriptions may be substantially the same as the description of the printed circuit board 100A and the method of manufacturing the same described above, and overlapping descriptions will not be provided.

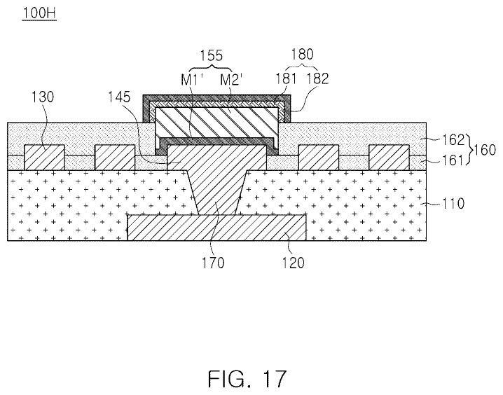

FIG. 17 is a cross-sectional diagram illustrating another example of a printed circuit board according to an example embodiment.

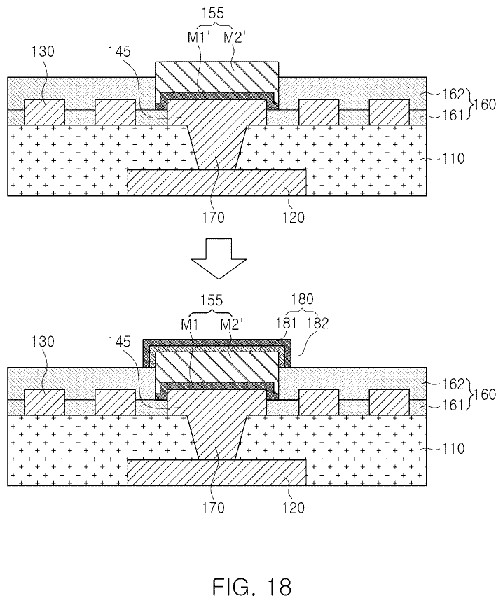

FIG. 18 is a process diagram illustrating an example of manufacturing the printed circuit board illustrated in FIG. 17 according to an example embodiment.

Referring to the diagram, differently from the printed circuit board 100B according to another example described above, in a printed circuit board 100H according to another example, a surface treatment layer 180 may be disposed on a portion of the conductive bump 155 exposed from the solder resist layer 160, for example, the second solder resist layer 162. Also, the method of manufacturing the printed circuit board 100H according to another example may further include forming a surface treatment layer 180 on a portion of the conductive bumps 155 exposed from a solder resist layer 160, for example, a second solder resist layer 162, differently from the method of manufacturing the printed circuit board 100B according to another example described above. The surface treatment layer 180 may include a first surface treatment layer 181 disposed on an exposed portion of the conductive bumps 155 and a second surface treatment layer 182 disposed on the first surface treatment layer 181. Each of the first and second surface treatment layers 181 and 182 may include nickel (Ni) and gold (Au), but an embodiment thereof is not limited thereto, and various other materials may be used. For example, the forming the surface treatment layer 180 may include electroless nickel/immersion gold (ENIG), electroless nickel/electroless palladium/immersion gold (ENEPIG), and/or electrolytic nickel/gold plating (ENGP) processes, but an embodiment thereof is not limited thereto, and hot air solder leveling (HASL), immersion silver (ImAg), and/or immersion tin (ImSn) may be included, and organic solderability preservative (OSP) process may be included. When the surface treatment layer 180 is formed, reliability may be ensured during die bonding in the packaging step. Also, copper consumption may be prevented.

Other descriptions may be substantially the same as the description of the printed circuit board 100B and the method of manufacturing the same described above, and overlapping descriptions will not be provided.

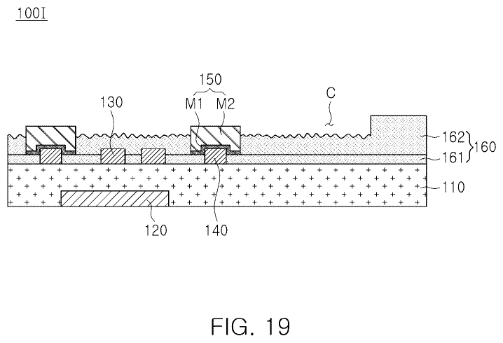

FIG. 19 is a cross-sectional diagram illustrating another example of a printed circuit board according to an example embodiment.

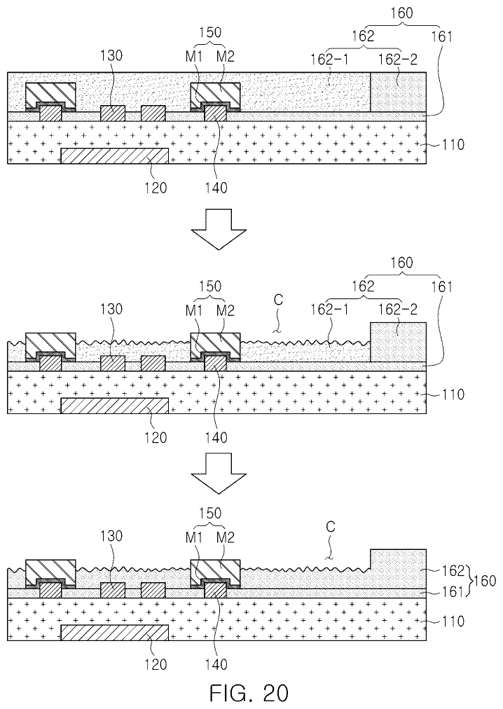

FIG. 20 is a process diagram illustrating an example of manufacturing the printed circuit board illustrated in FIG. 19 according to an example embodiment.

Referring to the diagram, differently from the printed circuit board 100A according to the above-described example, in a printed circuit board 100I according to another example, the solder resist layer 160, for example, the second solder resist layer 162, may have a cavity C exposing a portion of each of the plurality of conductive bumps 150 from the solder resist layer 160, for example, the second solder resist layer 162, and the upper surface of the solder resist layer 160, for example, the second solder resist layer 162, may have a step difference due to the cavity C. Also, differently from the method of manufacturing a printed circuit board 100A according to the above-described example, according to another example, in the method of manufacturing the printed circuit board 100I, reducing the thickness of the second solder resist layer 162 may include forming a cavity C exposing a portion of each of the plurality of conductive bumps 150 from the second solder resist layer 162, and an upper surface of the second solder resist layer 162 may have a step difference by the cavity C. The cavity C may be a blind cavity having a bottom surface. By the cavity C, the solder resist layer 160, for example, the second solder resist layer 162, may have a two-stage step difference structure.

The plurality of conductive bumps 150 and the corresponding plurality of conductive pads 140 may be disposed in a region overlapping the cavity C. The region overlapping cavity C may be disposed in the cavity C, for example, when viewed from the top and/or the side. The cavity C may be formed, for example, by curing the outer region 162-2 of the solder resist layer 160, for example, the second solder resist layer 162, with ultraviolet light, and etching the other uncured region 162-1. After the etching, if desired, curing of the uncured region 162-1 in which the cavity C is formed may be further performed. In this case, the upper surface of the solder resist layer 160 in the region in which cavity C is formed, for example, the upper surface of the second solder resist layer 162, may have the roughness described above, whereas the upper surface of the solder resist layer 160 in the region in which cavity C is not formed, for example, the upper surface of the second solder resist layer 162, may have a smooth surface. For example, the upper surface of the solder resist layer 160 in the region in which the cavity C is formed, for example, the upper surface of the second solder resist layer 162, may have surface roughness greater than that of the upper surface of the solder resist layer 160 in the region in which the cavity C is not formed, for example, the upper surface of the second solder resist layer 162. The surface roughness may indicate average roughness Ra, and may be several microns to several tens of microns, but an embodiment thereof is not limited thereto.

The level of the solder resist layer 160, for example, the second solder resist layer 162, may be selectively reduced only in the region in which the die is mounted, and roughness may also be provided to the surface. Accordingly, the die may be effectively mounted in the packaging stage, and reliability may be increased.

Other descriptions may be substantially the same as the description of the printed circuit board 100A and the method of manufacturing the same described above, and overlapping descriptions will not be provided.

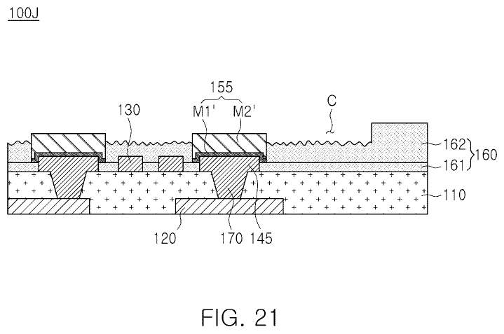

FIG. 21 is a cross-sectional diagram illustrating another example of a printed circuit board according to an example embodiment.

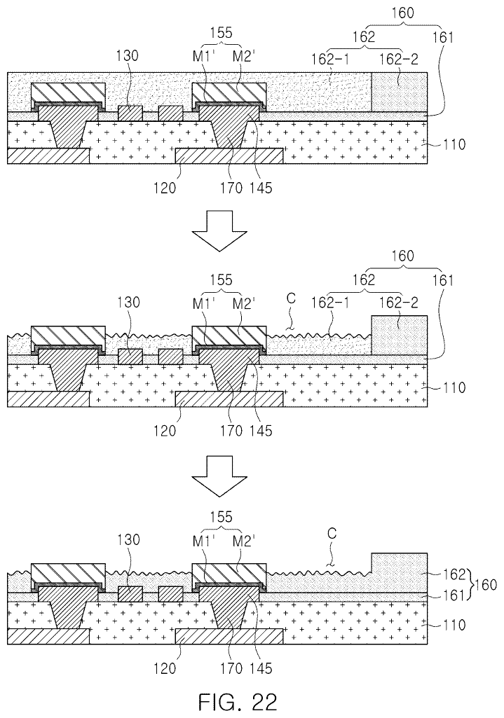

FIG. 22 is a process diagram illustrating an example of manufacturing the printed circuit board illustrated in FIG. 21 according to an example embodiment.

Referring to the diagram, in a printed circuit board 100J according to another example, differently from the printed circuit board 100B according to another example described above, a solder resist layer 160, for example, the second solder resist layer 162, may have a cavity C exposing a portion of each of the plurality of conductive bumps 155 from the solder resist layer 160, for example, the second solder resist layer 162, and the upper surface of the solder resist layer 160, for example, the second solder resist layer 162, may have a step difference due to the cavity C. Also, in a method of manufacturing the printed circuit board 100I according to another example may include, differently from the method of manufacturing the printed circuit board 100B according to another example described above, reducing the thickness of the second solder resist layer 162 may include forming a cavity C in the second solder resist layer 162 exposing a portion of each of a plurality of conductive bumps 155 from the second solder resist layer 162, and an upper surface of the second solder resist layer 162 may have a step difference by the cavity C. The cavity C may be a blind cavity having a bottom surface. By the cavity C, the solder resist layer 160, for example, the second solder resist layer 162, may have a two-stage step difference structure.

The plurality of conductive bumps 155 and a plurality of conductive pads 145 corresponding thereto may be disposed in a region overlapping the cavity C. The region overlapping the cavity C may be disposed in the cavity C, for example, when viewed from the top and/or the side. The cavity C may be formed, for example, by curing an outer region 162-2 of a solder resist layer 160, for example, a second solder resist layer 162, with ultraviolet light, and etching the other uncured region 162-1. After etching, if desired, curing the uncured region 162-1 in which the cavity C is formed may be further performed. In this case, the upper surface of the solder resist layer 160 in the region in which the cavity C is formed, for example, the upper surface of the second solder resist layer 162, may have roughness as described above, whereas the upper surface of the solder resist layer 160 in the region in which the cavity C is not formed, for example, the upper surface of the second solder resist layer 162, may have a smooth surface. For example, the upper surface of the solder resist layer 160 in the region in which the cavity C is formed, for example, the upper surface of the second solder resist layer 162, may have surface roughness greater than that of the upper surface of the solder resist layer 160 in the region in which the cavity C is not formed, for example, the upper surface of the second solder resist layer 162. The surface roughness may indicate average roughness Ra, and may be several microns to several tens of microns, but an embodiment thereof is not limited thereto.

The level of the solder resist layer 160, for example, the second solder resist layer 162, may be selectively reduced only in the region in which the die is mounted, and roughness may also be provided to the surface. Accordingly, the die may be effectively mounted at the packaging stage, and reliability may be increased.

Other descriptions may be substantially the same as the description of the printed circuit board 100B and the method of manufacturing the same described above, and overlapping descriptions will not be provided.

The structures of the printed circuit boards 100A, 100B, 100C, 100D, 100E, 100F, 100G, 100H, 100I, and 100J described above may be combined with each other as long as the combinations are not contradictory. Also, the methods of manufacturing the printed circuit boards 100A, 100B, 100C, 100D, 100E, 100F, 100G, 100H, 100I, and 100J described above may be combined with each other as long as the combinations are not contradictory.

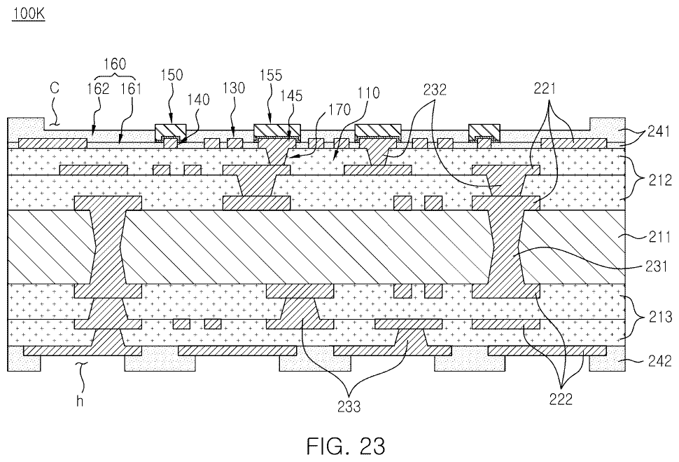

FIG. 23 is a cross-sectional diagram illustrating another example of a printed circuit board according to an example embodiment.

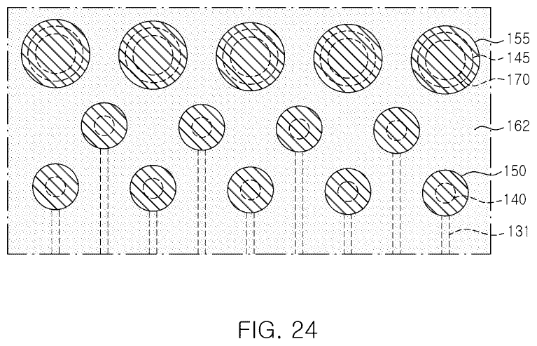

FIG. 24 is a plan diagram illustrating a top view of the printed circuit board illustrated in FIG. 23.

Referring to the diagram, a printed circuit board 100K according to another example may include a multilayer substrate structure including a plurality of insulating layers 211, 212, and 213, a plurality of interconnection layers 221 and 222, and a plurality of via layers 231, 232, and 233. The multilayer substrate structure may be a core type multilayer substrate structure. For example, the plurality of insulating layers 211, 212, and 213 may include a core insulating layer 211, and the core insulating layer 211 may have a thickness greater than that of each of the other insulating layers 212 and 213. However, an embodiment thereof is not limited thereto, and the multilayer substrate structure may also be a coreless type multilayer substrate structure if desired. The printed circuit board 100K according to another example may have a multilayer substrate structure and may be easily used as a package substrate and/or an interposer substrate on which a die is mounted. A first passivation layer 241 may be disposed on the upper side of the plurality of insulating layers 211, 212, and 213, and a second passivation layer 142 may be disposed on the lower side of the plurality of insulating layers 211, 212, and 213.

Among the plurality of insulating layers 211, 212, and 213, the uppermost insulating layer 212 may include the insulating layer 110 described in the embodiments of the printed circuit boards 100A, 100B, 100C, 100D, 100E, 100F, 100G, 100H, 100I, and 100J described above. Also, among the plurality of interconnection layers 221 and 222, the uppermost interconnection layer 221 may include the second conductive pattern 130 and conductive pads 140 and 145 described in the embodiments of the printed circuit boards 100A, 100B, 100C, 100D, 100E, 100F, 100G, 100H, 100I, and 100J, and conductive bumps 150 and 155 may be disposed on the conductive pads 140 and 145, respectively. In this case, the conductive pad 145 may have a maximum width greater than that of the conductive pad 140, and the conductive bump 155 may have a maximum width greater than that of the conductive bump 145. Also, the interconnection layer 221 disposed immediately below the uppermost interconnection layer 221 among the plurality of interconnection layers 221 and 222 may include the first conductive pattern 120 described in the embodiments of the printed circuit boards 100A, 100B, 100C, 100D, 100E, 100F, 100G, 100H, 100I, and 100J described above. Also, the uppermost via layer 233 among the plurality of via layers 231, 232, and 233 may include a conductive via (not illustrated) or a conductive via 170 described in the embodiments of the printed circuit boards 100A, 100B, 100C, 100D, 100E, 100F, 100G, 100H, 100I, and 100J described above. Also, the first passivation layer 241 may include the solder resist layer 160 described in the embodiments of the printed circuit boards 100A, 100B, 100C, 100D, 100E, 100F, 100G, 100H, 100I, and 100J, for example, the first and second solder resist layers 161 and 162.

The second conductive pattern 130 included in the uppermost interconnection layer 221 among the plurality of interconnection layers 222 may include a plurality of conductive lines 131. The plurality of conductive lines 131 may be connected to a portion of the plurality of conductive pads 140 and 145, for example, the conductive pads 140 having a relatively small size. At least a portion of the plurality of conductive lines 131 may be disposed between at least two of the plurality of conductive pads 140 and 145 on the plane, for example, between at least two of the conductive pads 140 having a relatively small size. In this case, the conductive bumps 145 and 155 may be formed on the plurality of conductive pads 140 and 145, respectively, such that the risk of side effects occurring when arranging the plurality of conductive lines 131 between the plurality of conductive pads 140 and 145, for example, between the conductive pads 140 having a relatively small size, may be addressed.

The methods of manufacturing the printed circuit boards 100A, 100B, 100C, 100D, 100E, 100F, 100G, 100H, 100I, and 100J described above may further include forming a multilayer substrate structure of the printed circuit board 100K according to another example described above.

Hereinafter, the components of the printed circuit board 100K according to another example may be described in greater detail with reference to the diagram.

A plurality of insulating layers 211, 212, and 213 may include a core insulating layer 211, a plurality of first built-up insulating layers 212 laminated on an upper surface of the core insulating layer 211, and a plurality of second built-up insulating layers 213 laminated on a lower surface of the core insulating layer 211. Each of the core insulating layer 211 and the plurality of first and second built-up insulating layers 212 and 213 may include an insulating material. The insulating material may be a thermosetting resin such as an epoxy resin, a thermoplastic resin such as a polyimide, a material in which these insulating resins are mixed with an inorganic filler such as silica, or a resin impregnated into a core material such as glass fiber together with an inorganic filler. For example, the core insulating layer 211 may include an insulating material of a copper clad laminate (CCL) and/or a prepreg. Each of the plurality of first and second built-up insulating layers 212 and 213 may include prepreg, Ajinomoto build-up film (ABF), photo image-able dielectric (PID), and/or resin coated copper (RCC). The plurality of first and second built-up insulating layers 212 and 213 may have a symmetrical structure, for example, may have the same number of layers. However, an embodiment thereof is not limited thereto, and the plurality of first and second built-up insulating layers 212 and 213 may have an asymmetrical structure, for example, may have different numbers of layers.

The plurality of interconnection layers 221 and 222 may include a plurality of first built-up interconnection layers 221 disposed on or in the plurality of first built-up insulating layers 212, and a plurality of second built-up interconnection layers 222 disposed on or in the plurality of second built-up insulating layers. Each of the plurality of first and second built-up interconnection layers 221 and 222 may include a metal. The metal may include copper (Cu), aluminum (Al), silver (Ag), tin (Sn), gold (Au), nickel (Ni), lead (Pb), titanium (Ti), and/or alloys thereof. Each of the plurality of first and second built-up interconnection layers 221 and 222 may include chemical copper formed by electroless plating as a seed layer, and may include electrolytic copper formed by electrolytic plating based on chemical copper as a plating layer, but an embodiment thereof is not limited thereto. If desired, the seed layer may include sputtered titanium and/or sputtered copper formed by sputtering, or may further include the material together with chemical copper. Each of the plurality of first and second built-up interconnection layers 221 and 222 may perform various functions depending on a design. For example, each of the plurality of first and second built-up interconnection layers 221 and 222 may include a signal transmission pattern, a power transmission pattern, a ground transmission pattern, or the like. These patterns may have various pattern forms such as a line, a trace, a plane, a pad, and a land. The plurality of first and second built-up interconnection layers 221 and 222 may have the same number of layers, but an embodiment thereof is not limited thereto, and the number of layers may be different.

The plurality of via layers 231, 232, and 233 may include a core via layer 231 penetrating at least a portion of the core insulating layer 211, a plurality of first built-up via layers 232 penetrating at least a portion of the plurality of first built-up insulating layers 212, and a plurality of second built-up via layers 233 penetrating at least a portion of the plurality of second built-up insulating layers 213, respectively. The plurality of first and second built-up interconnection layers 221 and 222 may be electrically connected to each other through the core via layer 231 and the plurality of first and second built-up via layers 232 and 233. Each of the core via layer 231 and the plurality of first and second built-up via layers 232 and 233 may include a metal. The metal may include copper (Cu), aluminum (Al), silver (Ag), tin (Sn), gold (Au), nickel (Ni), lead (Pb), titanium (Ti), and/or alloys thereof. For example, each of the core via layer 231 and the plurality of first and second built-up via layers 232 and 233 may include chemical copper formed by electroless plating as a seed layer, and may include electrolytic copper formed by electrolytic plating based on chemical copper as a plating layer, but an embodiment thereof is not limited thereto. If desired, sputtered titanium and/or sputtered copper formed by sputtering may be included as the seed layer, or the material may be further included together with chemical copper. Each of the core via layer 231 and the plurality of first and second built-up via layers 232 and 233 may perform various functions depending on a design. For example, each of the core via layer 231 and the plurality of first and second built-up via layers 232 and 233 may include a signal transmission via, a power transmission via, and a ground transmission via. The through-vias included in the core via layer 231 may have substantially an hourglass shape or a cylindrical shape. Each of the connection vias included in the plurality of first built-up via layers 232 may have a substantially tapered shape, tapered in an opposite direction to the connection vias included in the plurality of second built-up via layers 233. The plurality of first and second built-up via layers 232 and 233 may have the same number of layers, but an embodiment thereof is not limited thereto, and the number of layers may be different.

Each of the first and second passivation layers 241 and 242 may include an insulating material. The insulating material may include a thermosetting resin such as an epoxy resin, a thermoplastic resin such as a polyimide, or a resin together with an inorganic filler and/or an organic filler. For example, each of the first and second passivation layers 241 and 242 may include Ajinomoto build-up film (ABF), solder resist (SR), or the like, but an embodiment thereof is not limited thereto. Each of the first and second passivation layers 241 and 242 may be of a liquid type or a film type, but an embodiment thereof is not limited thereto. The first passivation layer 241 may have a plurality of blind-shaped cavities C exposing a portion a of each of the conductive bumps 150. The second passivation layer 242 may have a plurality of openings h exposing at least a portion of the second built-up interconnection layer 222 on the lowermost side, respectively. Each of the patterns exposed by the plurality of openings h may be solder mask defined (SMD) and/or non-solder mask defined (NSMD) types.

Other descriptions may be substantially the same as the descriptions of the printed circuit boards 100A, 100B, 100C, 100D, 100E, 100F, 100G, 100H, 100I, and 100J and the method of manufacturing the printed circuit boards 100A, 100B, 100C, 100D, 100E, 100F, 100G, 100H, 100I, and 100J, and overlapping descriptions will not be provided.

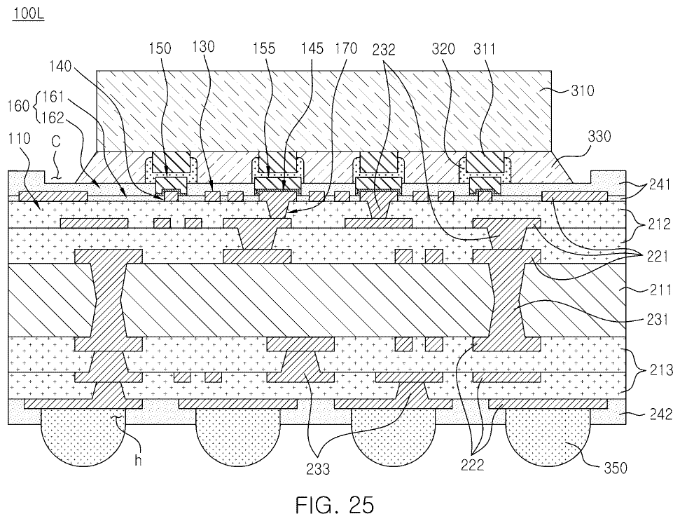

FIG. 25 is a cross-sectional diagram illustrating another example of a printed circuit board.

Referring to the diagram, a printed circuit board 100L according to another example may further include a semiconductor chip 310 mounted on a first passivation layer 241 in the printed circuit board 100K according to another example described above. The semiconductor chip 310 may have a plurality of electrodes 311 on a mounting surface, and the plurality of electrodes 311 may be connected to a plurality of bumps 150 through a plurality of connection members 320, respectively. An underfill 330 may be disposed between the first passivation layer 241 and the semiconductor chip 310. The underfill 330 may cover at least a portion of each of the plurality of electrodes 311 and the plurality of connection members 320. Bonding reliability of the semiconductor chip 310 may be improved through the underfill 330. A plurality of electrical connection metals 350 may be disposed on the plurality of openings h of the second passivation layer 142, respectively. the printed circuit board 100L according to another example may have a semiconductor package structure.

In the description below, the components of the printed circuit board 100L according to another example will be described in greater detail with reference to the diagram.

The semiconductor chip 310 may include an integrated circuit (IC) die in which hundreds to millions of elements are integrated into a single chip. In this case, the integrated circuit may be implemented as, for example, a logic chip such as a central processor (e.g., CPU), a graphics processor (e.g., GPU), a field programmable gate array (FPGA), a digital signal processor, an encryption processor, a microprocessor, a microcontroller, an application processor (e.g., AP), an analog-to-digital converter, an application-specific IC (ASIC), but an embodiment thereof is not limited thereto, and the integrated circuit may be another type such as a memory chip such as a volatile memory (e.g., DRAM), a non-volatile memory (e.g., ROM), a flash memory, a high bandwidth memory (HBM), or a power management IC (PMIC). A plurality of the semiconductor chip 310 may be provided, and in this case, the plurality of semiconductor chips 310 may be the same or different from each other.

The plurality of electrodes 311 may be disposed on an active surface of the semiconductor chip 310, for example, an active surface of the die. The plurality of electrodes 311 may include a metal, and the metal may include copper (Cu), aluminum (Al), silver (Ag), tin (Sn), gold (Au), nickel (Ni), lead (Pb), titanium (Ti), and/or alloys thereof. Each of the plurality of electrodes 311 may have a structure including a pad, a bump, a post, or a combination thereof.

Each of the plurality of connection members 320 and the plurality of electrical connection metals 350 may be formed of a low melting point metal, for example, solder such as tin (Sn)-aluminum (Al)-copper (Cu), but an embodiment thereof is not limited thereto and the material is not limited to any particular example. Each of the plurality of connection members 320 and the plurality of electrical connection metals 350 may include a solder ball or a solder bump. The plurality of connection members 320 and the plurality of electrical connection metals 350 may be formed in multiple layers or a single layer, but an embodiment thereof is not limited thereto.

The underfill 330 may be formed based on an epoxy resin, and may include an inorganic filler, or the like, for a low coefficient of thermal expansion (CTE), but the material is not limited to any particular example. The underfill 330 may have high adhesive strength, low viscosity, excellent thermal conductivity, mechanical strength, or the like. Accordingly, reliability of the semiconductor chip 310 may be improved.

Other descriptions may be substantially the same as the description of the printed circuit boards 100A, 100B, 100C, 100D, 100E, 100F, 100G, 100H, 100I, and 100J, 100K and the method of manufacturing the printed circuit boards 100A, 100B, 100C, 100D, 100E, 100F, 100G, 100H, 100I, and 100J, and overlapping descriptions will not be provided.

According to the aforementioned example embodiments, the level and/or size of the conductive bump may be increased separately from a design rule of the conductive pad, and accordingly, a printed circuit board having improved die bonding reliability and underfill formation stability may be provided.

Also, the size of the conductive pad may be reduced, and accordingly, a printed circuit board having improved circuit density and circuit design freedom may be provided.

In the present disclosure, the term “covering” may include covering entirely and may also cover at least a portion, and may also include covering directly and may also cover indirectly. Also, the term “filling” may include filling completely and also filling roughly, and may include, for example, the presence of some gaps or voids. Also, the expression of surrounding may include not only the case of completely surrounding, but also the case of surrounding a portion and the case of roughly surrounding. Also, exposing may include completely exposing, and also partially exposing, and exposure may indicate being exposed from embedding the corresponding component. For example, opening exposing a pad may indicate exposing the pad from the resist layer, and a surface treatment layer may be disposed on the exposed pad.

In the present disclosure, process errors, positional deviations, and measurement errors occurring in the manufacturing process may be included. For example, the notion that the line width, distance, thickness, and level are substantially the same may include case in which the elements are completely the same in numerical sense, and also case in which the elements may have similar values. Also, the notion of “having substantially a predetermined shape” may include case of having almost the same shape and also having a similar shape.

In the present disclosure, the term “on a cross-section” may indicate the cross-sectional shape when the object is cut vertically, or the cross-sectional shape when the object is viewed from the side. Also, the term “on a plane” may indicate the plane shape when the object is cut horizontally, or the plane shape when the object is viewed from the top or bottom.

The terms “lower side,” “lower portion,” “lower surface,” and the like, may be used to refer to a surface formed in a downward direction with reference to a cross-section in the diagrams for ease of description, the terms “upper side,” “upper portion,” “upper surfaces,” and the like, may be used to refer to a surface formed in an upward direction, and the terms “side portion,” “side surface,” and the like, may be used to refer to a surface formed taken in the direction perpendicular to an upper surface and lower surface. The terms, however, may be defined as above for ease of description, and the scope of right of the example embodiments is not particularly limited to the above terms.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” Also, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, thickness, width, length, pitch, depth, or the like, may be measured using a scanning microscope or optical microscope based on a cross-section of a printed circuit board polished or cut out. The cross-section may be a vertical cross-section or a horizontal cross-section, and each value may be measured based on the required cross-section. For example, the width of the upper end and/or lower end of a via may be measured on a cross-section taken along the central axis of the via. In this case, when the values are not constant, the values may be determined as the average of the values measured at arbitrary five points.

In the example embodiments, the term “example embodiment” may not refer to one same example embodiment, and may be provided to describe and emphasize different unique features of each example embodiment. The above suggested example embodiments may be implemented in combination with features of other embodiments, unless otherwise specified. For example, even though the features described in one example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
an insulating layer;
a conductive pad disposed on the insulating layer;
a conductive bump disposed on the insulating layer, spaced apart from the insulating layer, and covering at least a portion of the conductive pad; and
a solder resist layer disposed on the insulating layer, and covering at least a portion of each of the conductive pad and the conductive bump,
wherein the conductive bump has a maximum width greater than a maximum width of the conductive pad.

2. The printed circuit board of claim 1,
wherein at least a portion of the solder resist layer is disposed between an upper surface of the insulating layer and a lower surface of the conductive bump, and
wherein a lower surface of the conductive bump is in direct contact with the solder resist layer.

3. The printed circuit board of claim 1,
wherein the solder resist layer covers a portion of a side surface of the conductive pad, and
wherein the conductive bump covers an upper surface and an other portion of the side surface of the conductive pad.

4. The printed circuit board of claim 1,
wherein the solder resist layer covers a portion of a side surface of the conductive bump, and
wherein an upper surface and an other portion of the side surface of the conductive bump protrude to an upper surface of the solder resist layer.

5. The printed circuit board of claim 1,
wherein the conductive pad has first and second side surfaces opposing each other,
wherein the conductive bump has third and fourth side surfaces opposing each other, and
wherein the third side surface and the fourth side surface of the conductive bump protrude toward an outer side relative to the first side surface and the second side surface of the conductive pad, respectively.

6. The printed circuit board of claim 5, wherein a length protruding from the first side surface to the third side surface is different from a length protruding from the second side surface to the fourth side surface.

7. The printed circuit board of claim 1,
wherein the conductive bump includes a seed layer and a metal layer disposed on the seed layer, and
wherein the seed layer is in direct contact with at least a portion of each of the conductive pad and the solder resist layer.

8. The printed circuit board of claim 7, wherein at least a portion of a side surface of the seed layer is recessed toward an inner side relative to a side surface of the metal layer.

9. The printed circuit board of claim 7,
wherein the seed layer includes a plurality of seed layers, and
wherein one or more of the plurality of seed layers include a metal different from a metal of the metal layer.

10. The printed circuit board of claim 9,
wherein the plurality of seed layers include sputter titanium and sputter copper, and
wherein the metal layer includes electrolytic copper.

11. The printed circuit board of claim 1, wherein at least a portion of an upper surface of the solder resist layer has surface roughness greater than that of one or more of a surface in contact with a side surface of the conductive pad of the solder resist layer and a surface in contact with a side surface of the conductive bump of the solder resist layer.

12. The printed circuit board of claim 1, wherein a surface in contact with a lower surface of the conductive bump of the solder resist layer has surface roughness greater than that of one or more of a surface in contact with a side surface of the conductive pad of the solder resist layer and a surface in contact with a side surface of the conductive bump of the solder resist layer.

13. The printed circuit board of claim 1,
wherein a portion of the conductive bump is exposed from the solder resist layer, and
wherein a surface treatment layer is disposed on an exposed portion of the conductive bump.

14. The printed circuit board of claim 13,
wherein the surface treatment layer includes a first surface treatment layer disposed on an exposed portion of the conductive bump and a second surface treatment layer disposed on the first surface treatment layer,
wherein the first surface treatment layer includes nickel (Ni), and
wherein the second surface treatment layer includes gold (Au).

15. The printed circuit board of claim 1,
wherein the solder resist layer has a cavity exposing a portion of the conductive bump from the solder resist layer, and
wherein an upper surface of the solder resist layer comprises a step difference formed by the cavity.

16. The printed circuit board of claim 1,
wherein the solder resist layer includes a first solder resist layer disposed on the insulating layer and covering a portion of a side surface of the conductive pad, and a second solder resist layer disposed on the first solder resist layer and covering a portion of a side surface of the conductive bump,
wherein the first solder resist layer has a thickness less than a thickness of the conductive pad, and
wherein the second solder resist layer has a thickness less than a thickness of the conductive bump.

17. The printed circuit board of claim 16,
wherein at least a portion of an upper surface of the first solder resist layer has surface roughness greater than that of a surface in contact with a side surface of the conductive pad of the first solder resist layer, and
wherein at least a portion of an upper surface of the second solder resist layer has surface roughness greater than that of a surface in contact with a side surface of the conductive bump of the second solder resist layer.

18. The printed circuit board of claim 16, wherein the first and second solder resist layers are integrated with each other such that a boundary therebetween is not distinct.

19. The printed circuit board of claim 16, further comprising:
a conductive pattern disposed in the insulating layer; and
a conductive via penetrating at least a portion of the insulating layer and connected to the conductive pattern.

20. The printed circuit board of claim 19,
wherein a lower surface of the conductive pad is entirely in contact with the insulating layer, and
wherein the conductive pad is not directly connected to the conductive via.

21. The printed circuit board of claim 19,
wherein at least a portion of a lower surface of the conductive pad is in contact with the insulating layer, and at least an other portion of a lower surface is in contact with the conductive via, and
wherein the conductive pad is directly connected to the conductive via.

22. The printed circuit board of claim 1,
wherein the printed circuit board includes a multilayer substrate structure including a plurality of insulating layers, a plurality of interconnection layers, and a plurality of via layers,
wherein an uppermost insulating layer among the plurality of insulating layers includes the insulating layer, and
wherein an uppermost interconnection layer among the plurality of interconnection layers includes the conductive pad.

23. The printed circuit board of claim 22,
wherein the plurality of insulating layers include a core insulating layer, a plurality of first built-up insulating layers disposed on an upper surface of the core insulating layer, and a plurality of second built-up insulating layers disposed on a lower surface of the core insulating layer,
wherein the plurality of interconnection layers include a plurality of first built-up interconnection layers disposed on or within the plurality of first built-up insulating layers and a plurality of second built-up interconnection layers disposed on or within the plurality of second built-up insulating layers,
wherein the plurality of via layers include a through-via layer penetrating the core insulating layer, a plurality of first built-up via layers penetrating at least a portion of the plurality of first built-up insulating layers, respectively, and a plurality of second built-up via layers penetrating at least a portion of the plurality of second built-up insulating layers, respectively, and
wherein the core insulating layer has a thickness greater than a thickness of each of the plurality of first and second built-up insulating layers.

24. The printed circuit board of claim 22,
wherein a plurality of the conductive pads and a plurality of the conductive bumps are disposed,
wherein the uppermost interconnection layer further includes a plurality of conductive lines, and
wherein at least a portion of each of the plurality of conductive lines is disposed between at least two of the plurality of conductive pads on a plane.

25. The printed circuit board of claim 24,
wherein an uppermost side via layer among the plurality of via layers includes one or more conductive vias connected to one or more of the plurality of conductive pads, respectively,
wherein each of one or more conductive pads connected to the one or more conductive vias, respectively, among the plurality of conductive pads has a maximum width greater than that of each of one or more conductive pads not connected to the one or more conductive vias among the plurality of conductive pads.

26. A method of manufacturing a printed circuit board, the method comprising:
forming a conductive pad on an insulating layer;
forming a first solder resist layer covering the conductive pad on the insulating layer;
exposing a portion of the conductive pad from the first solder resist layer by reducing a thickness of the first solder resist layer;
forming a conductive bump covering an exposed portion of the conductive pad on the first solder resist layer;
forming a second solder resist layer covering the conductive bump on the first solder resist layer; and
exposing a portion of the conductive bump from the second solder resist layer by reducing a thickness of the second solder resist layer.

27. The method of claim 26, wherein the conductive bump is formed to have a maximum width greater than a maximum width of the conductive pad.

28. The method of claim 26, wherein the forming the conductive bump includes forming a seed layer on an upper surface of the first solder resist layer and an upper surface and a side surface of an exposed portion of the conductive pad, forming a plating layer on the seed layer, and removing the seed layer in a region of the upper surface of the first solder resist layer in which the plating layer is not formed by etching.

29. The method of claim 28,
wherein forming the seed layer includes forming a plurality of seed layers, and
wherein one or more of the plurality of seed layers include a metal different from a metal of the plating layer.

30. The method of claim 26,
wherein reducing a thickness of the first solder resist layer includes thinning the first solder resist layer by etching,
wherein reducing a thickness of the second solder resist layer includes thinning the second solder resist layer by etching, and
wherein roughness is formed on a thinned surface of the first and second solder resist layers, thinned by etching.

31. The method of claim 26, further comprising:
forming a surface treatment layer on an exposed portion of the conductive bump,
wherein forming the surface treatment layer includes at least one process selected from a group consisting of electroless nickel/immersion gold (ENIG) process, electroless nickel/electroless palladium/immersion gold (ENEPIG) process, and electrolytic nickel/gold plating (ENGP) process.

32. The method of claim 26,
wherein reducing a thickness of the second solder resist layer includes forming a cavity exposing a portion of the conductive bump on the second solder resist layer, and
wherein a step difference is formed in an upper surface of the second solder resist layer by the cavity.

33. The method of claim 26, further comprising:
forming a conductive pattern in the insulating layer; and
forming a conductive via penetrating at least a portion of the insulating layer and connected to the conductive pattern.

34. The method of claim 26, further comprising:
manufacturing a multilayer substrate structure including a plurality of insulating layers, a plurality of interconnection layers, and a plurality of via layers,
wherein an uppermost insulating layer among the plurality of insulating layers includes the insulating layer, and
wherein an uppermost interconnection layer among the plurality of interconnection layers includes the conductive pad.

35. The printed circuit board of claim 1,
wherein the solder resist layer includes a first solder resist layer disposed on the insulating layer and a second solder resist layer disposed on the first solder resist layer,
wherein the first solder resist layer includes an opening to expose an upper surface and a side surface of the conductive pad,
wherein a seed layer of the conductive bump extends along the exposed upper surface and the side surface of the conductive pad, and
wherein a portion of the conductive bump protrudes above an upper surface of the second solder resist layer.

36. The printed circuit board of claim 35,
wherein the seed layer includes a first seed layer comprising titanium in contact with the first solder resist layer, and a second seed layer comprising copper on the first seed layer,
and wherein the conductive bump further includes a metal layer comprising electrolytic copper on the seed layer.

37. The printed circuit board of claim 35,
wherein the second solder resist layer covers a side surface of the conductive bump while leaving the upper surface of the conductive bump exposed.
